(19) United States
(12) Patent Application Publication
(10) Pub. No.: US 2024/0203808 A1
(43) Pub. Date: Jun. 20, 2024

(54) SEMICONDUCTOR DEVICE

(71) Applicant: ROHM CO., LTD., Kyoto-shi (JP)

(72) Inventor: Koichi KITAGURO, Kyoto-shi (JP)

(21) Appl. No.: 18/420,385

(22) Filed: Jan. 23, 2024

Related U.S. Application Data
(63) Continuation of application No. PCT/JP2022/028605, filed on Jul. 25, 2022.

(30) Foreign Application Priority Data
Aug. 18, 2021 (JP) 2021-133495

(51) Int. Cl. H01L 23/31; H01L 23/00; H01L 23/495

(52) U.S. Cl. CPC H01L 23/3107; H01L 23/49555; H01L 24/32; H01L 24/48; H01L 24/73; H01L 2224/32245; H01L 2224/48175; H01L 2224/73265

(57) ABSTRACT

A semiconductor device includes a semiconductor element, a conductive member connected to the semiconductor element and a sealing resin covering the semiconductor element. The conductive member includes: a first lead including a mounting portion with the semiconductor element mounted thereon and a first terminal connected to the mounting portion; and a second lead including a second terminal. The first terminal and the second terminal include a portion protruding from the sealing resin in x direction. The sealing resin includes a resin obverse surface and a resin reverse surface facing away from each other in z direction. The sealing resin includes a resin end surface connected to the resin obverse surface and the resin reverse surface and facing in the direction in which the first and second terminals protrude. At the resin end surface, the first terminal and the second terminal are spaced apart in y direction and z direction.

### TECHNICAL FIELD

The present disclosure relates to a semiconductor device.

### BACKGROUND ART

For semiconductor devices having semiconductor elements, various configurations have been proposed. JP-A-2018-14490 discloses an example of a conventional semiconductor device. The semiconductor device disclosed in JP-A-2018-14490 includes a semiconductor element, a plurality of leads, and a sealing resin. The semiconductor element is mounted on a first lead, and the collector electrode on the reverse surface of the semiconductor element is electrically connected to the first lead. The emitter electrode on the obverse surface of the semiconductor element is electrically connected to the third lead. The sealing resin covers the semiconductor element and a portion of each lead. The first lead includes a first terminal protruding from the sealing resin, and the third lead includes a third terminal protruding from the sealing resin. Application of a high voltage (e.g., thousands of volts) between the first terminal and the third terminal may cause an electrical discharge along the surface of the sealing resin between the first terminal and the third terminal to short-circuit the first terminal and the third terminal.

### BRIEF DESCRIPTION OF THE DRAWINGS

FIG. 1 is a perspective view of a semiconductor device according to a first embodiment of the present disclosure.

FIG. 2 is a perspective view of the semiconductor device shown in FIG. 1, with a sealing resin shown as transparent.

FIG. 3 is a plan view of the semiconductor device shown in FIG. 1, with the sealing resin shown as transparent.

FIG. 4 is a bottom view of the semiconductor device shown in FIG. 1.

FIG. 5 is a front view of the semiconductor device shown in FIG. 1.

FIG. 6 is a sectional view taken along line VI-VI in FIG. 3.

FIG. 7 is a sectional view taken along line VII-VII in FIG. 3.

FIG. 8 is a bottom view of a semiconductor device according to a first variation of the first embodiment.

FIG. 9 is a sectional view of the semiconductor device shown in FIG. 8.

FIG. 10 is a sectional view of a semiconductor device according to a second variation of the first embodiment.

FIG. 11 is a sectional view of a semiconductor device according to a third variation of the first embodiment.

FIG. 12 is a sectional view of a semiconductor device according to a fourth variation of the first embodiment.

FIG. 13 is a sectional view of the semiconductor device shown in FIG. 12.

FIG. 14 is a sectional view of a semiconductor device according to a fifth variation of the first embodiment.

FIG. 15 is a sectional view of a semiconductor device according to a sixth variation of the first embodiment.

FIG. 16 is a sectional view of a semiconductor device according to a seventh variation of the first embodiment.

FIG. 17 is a plan view of a semiconductor device according to an eighth variation of the first embodiment, with a sealing resin shown as transparent.

FIG. 18 is a sectional view of a semiconductor device according to a second embodiment of the present disclosure.

FIG. 19 is a front view of the semiconductor device shown in FIG. 18.

FIG. 20 is a sectional view of a semiconductor device according to a first variation of the second embodiment.

FIG. 21 is a sectional view of a semiconductor device according to a third embodiment of the present disclosure.

FIG. 22 is a plan view of a semiconductor device according to a fourth embodiment of the present disclosure.

FIG. 23 is a front view of the semiconductor device shown in FIG. 22.

FIG. 24 is a sectional view taken along line XXIV-XXIV in FIG. 22.

FIG. 25 is a plan view of a semiconductor device according to a fifth embodiment of the present disclosure.

FIG. 26 is a front view of the semiconductor device shown in FIG. 25.

FIG. 27 is a front view of a semiconductor device according to a first variation of the fifth embodiment.

FIG. 28 is a plan view of a semiconductor device according to a sixth embodiment of the present disclosure.

FIG. 29 is a front view of the semiconductor device shown in FIG. 28.

FIG. 30 is a front view of a semiconductor device according to a first variation of the sixth embodiment.

FIG. 31 is a plan view of a semiconductor device according to a seventh embodiment of the present disclosure.

FIG. 32 is a front view of the semiconductor device shown in FIG. 31.

### DETAILED DESCRIPTION OF EMBODIMENTS

Hereinafter, preferred embodiments of the present disclosure will be specifically described with reference to the drawings.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

### First Embodiment

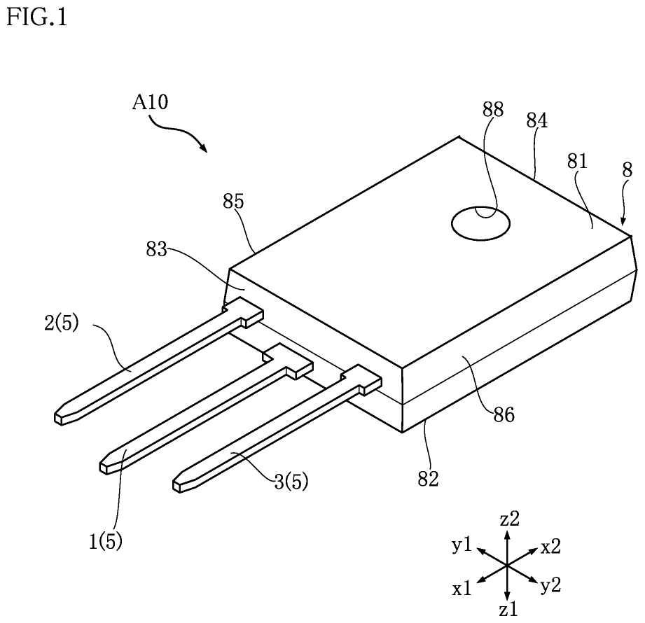

With reference to FIGS. 1 to 7, a semiconductor device A10 according to a first embodiment of the present disclosure will be described. The semiconductor device A10 includes a conductive member 5, a semiconductor element 6, wires 71 and 72, and a sealing resin 8.

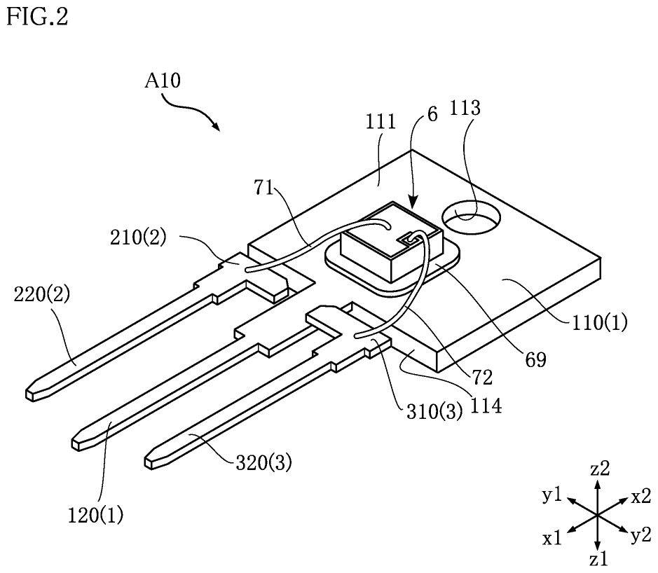

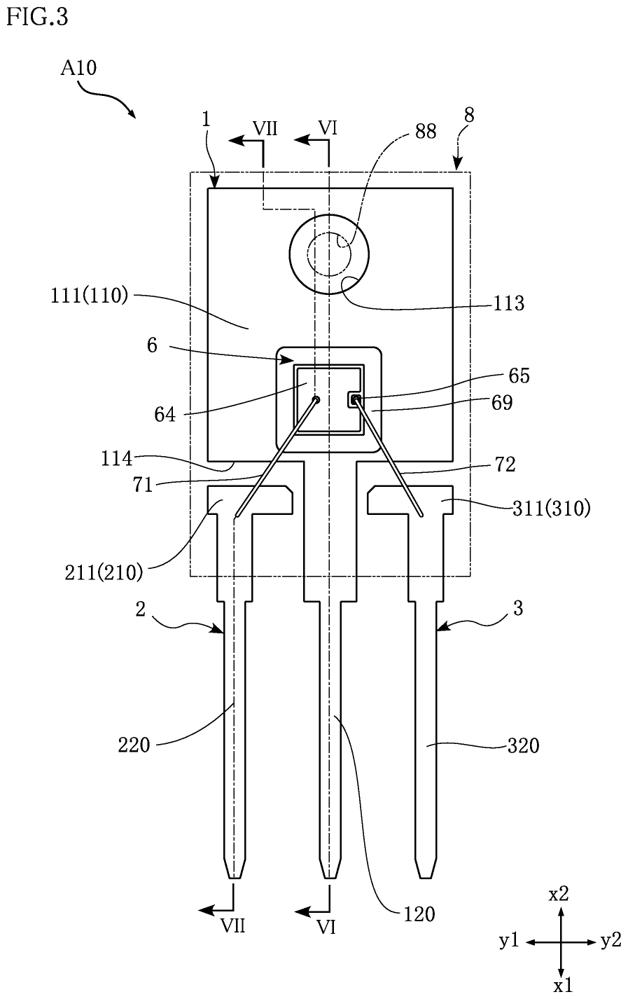

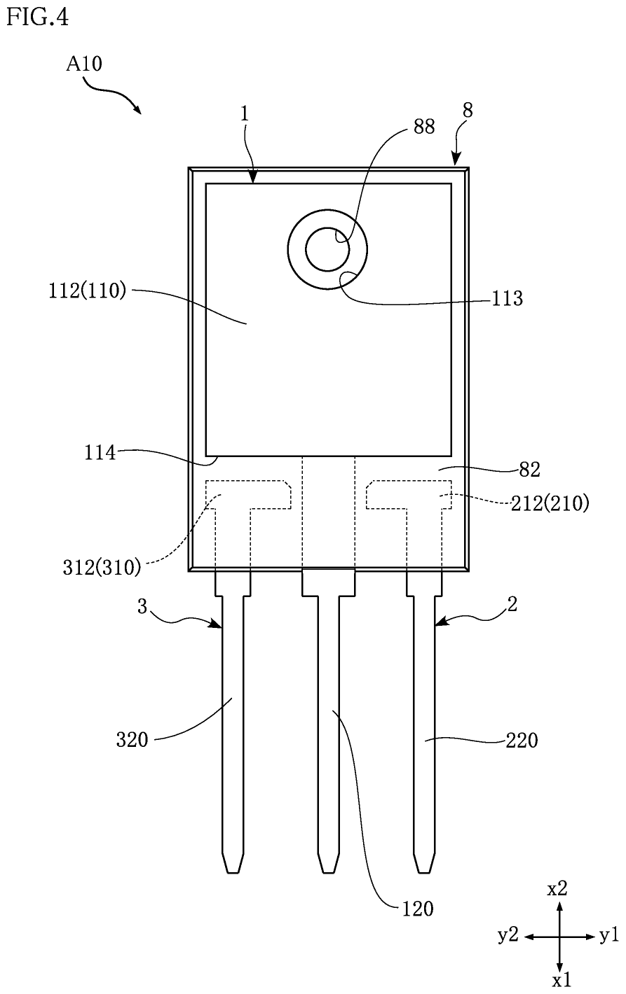

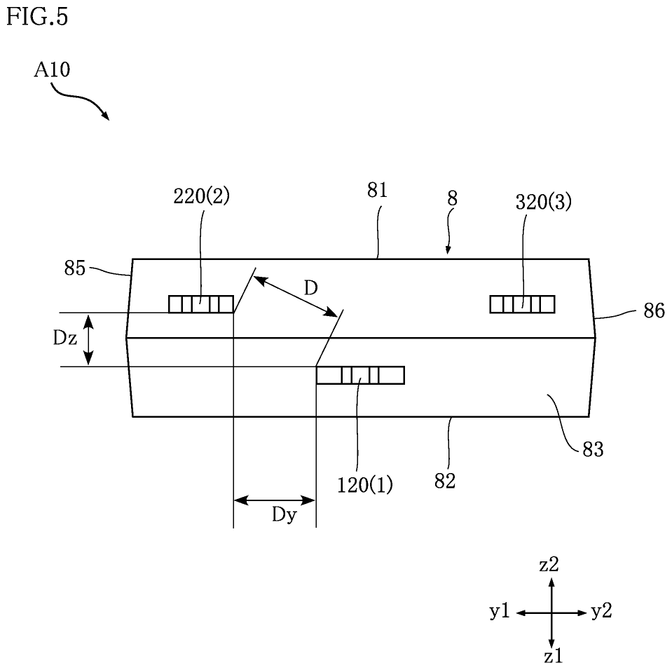

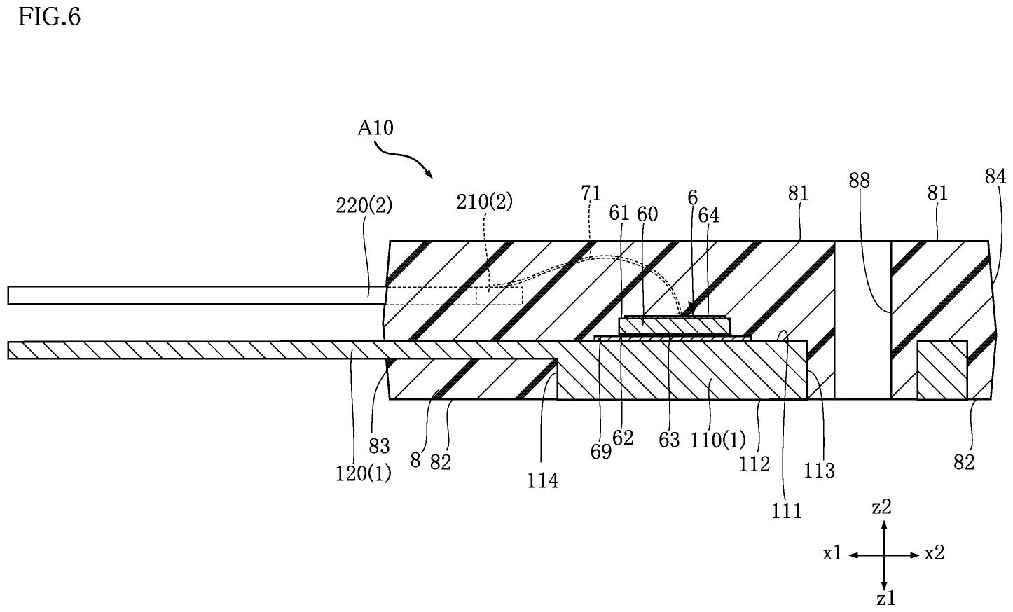

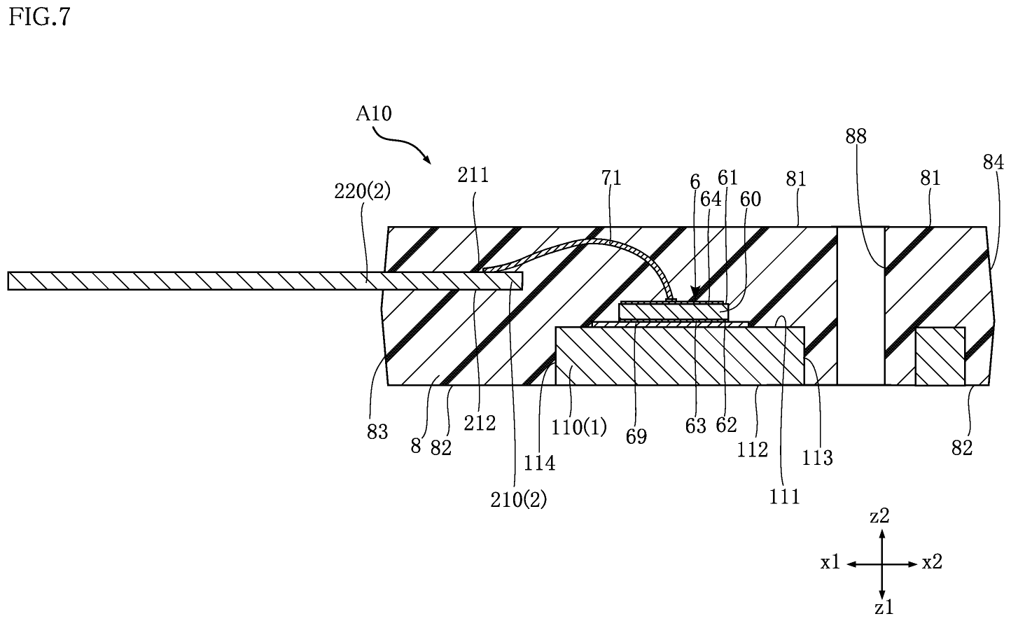

FIG. 1 is a perspective view of the semiconductor device A10. FIG. 2 is a perspective view of the semiconductor device A10. For convenience, FIG. 2 shows the sealing resin 8 as transparent. FIG. 3 is a plan view of the semiconductor device A10. For convenience, FIG. 3 shows the sealing resin 8 as transparent and indicates the outline of the sealing resin 8 with an imaginary line (two-dot-dash line). FIG. 4 is a bottom view of the semiconductor device A10. FIG. 5 is a front view of the semiconductor device A10. FIG. 6 is a sectional view taken along line VI-VI in FIG. 3. FIG. 7 is a sectional view taken along line VII-VII in FIG. 3.

The semiconductor device A10 shown in the figures is for mounting on a circuit board of various devices. The uses and functions of the semiconductor device A10 are not specifically limited. The semiconductor device A10 is provided in a single inline package (SIP), but the package of the semiconductor device A10 is not limited to SIP. The semiconductor device A10 has a portion covered with the sealing resin 8 that is rectangular as viewed in the thickness direction. For the convenience of description, the thickness direction (the plan-view direction) of the semiconductor device A10 is defined as a z direction, a direction orthogonal to the z direction and in which the terminals (a first lead 1, a second lead 2, and a third lead 3) of the semiconductor device A10 extend (the vertical direction in FIGS. 3 and 4) is defined as an x direction, and the direction orthogonal to the z direction and the x direction (the horizontal direction in FIGS. 3 and 4) is defined as a y direction. The x direction is an example of a “first direction”, and the y direction is an example of a “second direction”. The dimensions of the semiconductor device A10 are not specifically limited.

The conductive member 5 is electrically connected to the semiconductor element 6 to provide a conduction path between the semiconductor element 6 and the wiring of a circuit board when the semiconductor device A10 is mounted on the circuit board. The conductive member 5 is formed from a metal plate by punching and bending, for example. The conductive member 5 is made of metal, preferable examples of which include Cu, Ni, an alloy of Cu or Ni, and Alloy 42. The conductive member 5 in the present embodiment is Cu as an example. The thickness of the conductive member 5 is not specifically limited. The conductive member 5 includes a first lead 1, a second lead 2, and a third lead 3.

The first lead 1 supports the semiconductor element 6 and is electrically connected to the semiconductor element 6. The first lead 1 includes a mounting portion 110 and a first terminal 120.

The mounting portion 110 is for receiving the semiconductor element 6 thereon and has a rectangular (substantially rectangular) shape as viewed in the z direction. The mounting portion 110 has a mounting-portion obverse surface 111, a mounting-portion reverse surface 112, a mounting-portion end surface 114, and a mounting-portion through-hole 113. The mounting-portion obverse surface 111 and the mounting-portion reverse surface 112 face away from each other in the z direction. The mounting-portion obverse surface 111 faces the z2 side in the z direction. The mounting-portion obverse surface 111 is where the semiconductor element 6 is bonded. The mounting-portion reverse surface 112 faces the z1 side in the z direction. The mounting-portion reverse surface 112 is exposed from the sealing resin 8 and serves as a reverse-surface terminal. The mounting-portion end surface 114 is connected to the mounting-portion obverse surface 111 and the mounting-portion reverse surface 112 and faces the x1 side in the x direction. The mounting-portion through-hole 113 extends parallel to the z direction from the mounting-portion obverse surface 111 through to the mounting-portion reverse surface 112. The mounting-portion through-hole 113 is located at the center of the mounting portion 110 in the y direction and closer to the end on the x2 side in x direction (the upper side in FIGS. 3 and 4) and has a circular shape as viewed in the z direction. The location and the shape of the mounting-portion through-hole 113, however, are not specifically limited.

The first terminal 120 is connected to the mounting portion 110 and hence electrically connected to the semiconductor element 6 via the mounting portion 110. As shown in FIG. 3, the first terminal 120 has a width (a length in the y direction) smaller than the width (the length in the y direction) of the mounting portion 110. As shown in FIG. 6, in addition, the first terminal 120 has a thickness (a length in the z direction) smaller than the thickness (the length in the z direction) of the mounting portion 110. Conversely speaking, the mounting portion 110 is thicker than the first terminal 120. In the present embodiment, the first terminal 120 is connected at the center of the mounting-portion end surface 114 in the y direction as shown in FIG. 3 to the end of the mounting-portion end surface 114 on the z2 side in the z direction as viewed in FIG. 6. The position of the first terminal 120, however, is not specifically limited. The first terminal 120 extends in the x direction and has a portion protruding from the sealing resin 8. The first terminal 120 is wider at a portion extending from the mounting portion 110 to a location slightly beyond the sealing resin 8 than the tip portion extending therebeyond. The shape of the first lead 1, however, is not limited to the one described above. For example, the mounting portion 110 may be formed with a reverse-surface recess that is recessed from the mounting-portion reverse surface 112 toward the mounting-portion obverse surface 111 along the edges of the mounting-portion reverse surface 112. Covering the reverse-surface recess with the sealing resin 8 will prevent detachment of the first lead 1 from the sealing resin 8 to the z1 side in the z direction.

The second lead 2 is electrically connected to the semiconductor element 6. The second lead 2 is spaced apart from the first lead 1. As shown in FIG. 3, the second lead 2 is located on the x1 side of the mounting portion 110 of the first lead 1 in the x direction and the y1 side of the first terminal 120 in the y direction. In the z direction, the second lead 2 is located on the z2 side of the first lead 1 as shown in FIGS. 5 and 6. The second lead 2 includes a second pad portion 210 and a second terminal 220.

The second pad portion 210 is a portion to which the wire 71 is bonded and has a rectangular (or substantially rectangular) shape elongated in the y direction as viewed in the z direction. As shown in FIG. 7, the second pad portion 210 has a second-pad-portion obverse surface 211 and a second-pad-portion reverse surface 212. The second-pad-portion obverse surface 211 and the second-pad-portion reverse surface 212 face away from each other in the z direction. The second-pad-portion obverse surface 211 faces the z2 side in the z direction. The second-pad-portion obverse surface 211 has the wire 71 bonded thereto. The second-pad-portion reverse surface 212 faces the z1 side in the z direction. The second pad portion 210 is entirely covered with the sealing resin 8.

The second terminal 220 is connected to the second pad portion 210 and hence electrically connected to the semiconductor element 6 via the second pad portion 210 and the wire 71. As shown in FIG. 3, the second terminal 220 has a width (a length in the y direction) smaller than the width (the length in the y direction) of the second pad portion 210. As shown in FIG. 7, in addition, the second terminal 220 has a thickness (a length in the z direction) that is the same as the thickness (the length in the z direction) of the second pad portion 210 and also as the thickness of the first terminal 120. As shown in FIG. 3, the second terminal 220 is located on the x1 side of the second pad portion 210 in the x direction and closer to the y1 side in the y direction. Although the position of the second terminal 220 is not limited to this, the first terminal 120 and the second terminal 220 are preferably spaced apart in the y direction. The second terminal 220 extends in the x direction and has a portion protruding from the sealing resin 8. The second terminal 220 is wider at a portion extending from the second pad portion 210 to a location slightly beyond the sealing resin 8 than the tip portion extending therebeyond. The shape of the second lead 2, however, is not limited to the one described above.

The third lead 3 is electrically connected to the semiconductor element 6. The third lead 3 is spaced apart from the first lead 1 and the second lead 2. As shown in FIG. 3, the third lead 3 is located on the x1 side of the mounting portion 110 of the first lead 1 in the x direction and the y2 side of the first terminal 120 in the y direction. In the z direction, the third lead 3 is located on the z2 side of the first lead 1 as shown in FIG. 5. In the present embodiment, the second lead 2 and the third lead 3 coincide in position in the z direction. The third lead 3 includes a third pad portion 310 and a third terminal 320.

The third pad portion 310 is a portion to which the wire 72 is bonded and has a rectangular (or substantially rectangular) shape elongated in the y direction as viewed in the z direction. The third pad portion 310 has a third-pad-portion obverse surface 311 and a third-pad-portion reverse surface 312. The third-pad-portion obverse surface 311 and the third-pad-portion reverse surface 312 face away from each other in the z direction. The third-pad-portion obverse surface 311 faces the z2 side in the z direction. The third-pad-portion obverse surface 311 has the wire 72 bonded thereto. The third-pad-portion reverse surface 312 faces the z1 side in the z direction. The third pad portion 310 is entirely covered with the sealing resin 8.

The third terminal 320 is connected to the third pad portion 310 and hence electrically connected to the semiconductor element 6 via the third pad portion 310 and the wire 72. As shown in FIG. 3, the third terminal 320 has a width (a length in the y direction) smaller than the width (the length in the y direction) of the third pad portion 310. In addition, the third terminal 320 has a thickness (a length in the z direction) that is the same as the thickness (the length in the z direction) of the third pad portion 310 and also as the thickness of the first terminal 120. As shown in FIG. 3, the third terminal 320 is located on the x1 side of the third pad portion 310 in the x direction and closer to the y2 side in the y direction. Although the position of the third terminal 320 is not specifically limited, the first terminal 120 and the third terminal 320 are preferably spaced apart in the y direction. The third terminal 320 extends in the x direction and has a portion protruding from the sealing resin 8. The third terminal 320 is wider at a portion extending from the third pad portion 310 to a location slightly beyond the sealing resin 8 than the tip portion extending therebeyond. The shape of the third lead 3, however, is not limited to the one described above.

The portions of the first terminal 120, the second terminal 220, and the third terminal 320 exposed from the sealing resin 8 all have a similar shape. The tip of the first terminal 120 (the end opposite to the end connected to the mounting portion 110), the tip of the second terminal 220 (the end opposite to the end connected to the second pad portion 210), and the tip of the third terminal 320 (the opposite to the end connected to the third pad portion 310) are located at the same position in the x direction.

Optionally, an outer plating layer made of an Sn-based alloy, for example, may be provided to cover the portions of the first lead 1, the second lead 2, and the third lead 3 exposed from the sealing resin 8. In addition, an inner plating layer made of Ag, for example, may be provided to cover the region of the mounting-portion obverse surface 111 to which the semiconductor element 6 is bonded, the region of the second-pad-portion obverse surface 211 to which the wire 71 is bonded, and the region of the third-pad-portion obverse surface 311 to which the wire 72 is bonded.

The semiconductor element 6 is an element that exerts an electrical function of the semiconductor device A10. The semiconductor element 6 is not required to be of a specific type. In the present embodiment, the semiconductor element 6 is a transistor, such as a metal-oxide-semiconductor field-effect transistor (MOSFET). The semiconductor element 6 includes an element body 60, a first electrode 63, a second electrode 64, and a third electrode 65.

The element body 60 has the shape of a plate that is rectangular as viewed in the z direction. The element body 60 is made of a semiconductor material, which is silicon (Si) in this embodiment. The material of the element body 60 is not limited to Si, and other materials may be used, including silicon carbide (SiC) and gallium nitride (GaN). The element body 60 has an element obverse surface 61 and an element reverse surface 62. The element obverse surface 61 and the element reverse surface 62 face away from each other in the z direction. The element obverse surface 61 faces the z2 side in the z direction. The element reverse surface 62 faces the z1 side in the z direction. The second electrode 64 and the third electrode 65 are disposed on the element obverse surface 61. The first electrode 63 is disposed on the element reverse surface 62. In the present embodiment, the first electrode 63 is the drain electrode, the second electrode 64 is the source electrode, and the third electrode 65 is the gate electrode.

As shown in FIG. 3, the semiconductor element 6 is located at the center of the mounting-portion obverse surface 111 in the y direction and closer to the end in the x1 side in the x direction. The semiconductor element 6 does not overlap with the mounting-portion through-hole 113 as viewed in the z direction. As shown in FIGS. 6 and 7, the semiconductor element 6 is bonded to the mounting-portion obverse surface 111 via a bonding material 69, with the element reverse surface 62 facing toward the mounting-portion obverse surface 111. In the present embodiment, the bonding material 69 is a conductive bonding material, and solder in one example. Alternatively, the bonding material 69 may be other conductive bonding materials, including a silver paste and a sintered metal bonding material. Hence, the first electrode 63 of the semiconductor element 6 bonded to the mounting-portion obverse surface 111 via the bonding material 69 is electrically connected to the first lead 1.

The wire 71 is bonded to the second electrode 64 of the semiconductor element 6 and the second-pad-portion obverse surface 211 of the second lead 2. This electrically connects the second electrode 64 of the semiconductor element 6 to the second lead 2. The wire 72 is bonded to the third electrode 65 of the semiconductor element 6 and the third-pad-portion obverse surface 311 of the third lead 3. This electrically connects the third electrode 65 of the semiconductor element 6 to the third lead 3. Note that the wires 71 and 72 are not specifically limited as to the material, the thickness, and the number to be provided. Instead of the wires 72 and 73, other conductive connecting members (such as metal plates or metal ribbons) may be used to connect the semiconductor element 6 to the second lead 2 and the third lead 3. The first terminal 120 of the first lead 1 electrically connected to the first electrode 63 functions as the drain terminal of the semiconductor device A10, the second terminal 220 of the second lead 2 electrically connected to the second electrode 64 functions as the source terminal of the semiconductor device A10, and the third terminal 320 of the third lead 3 electrically connected to the third electrode 65 functions as the gate terminal of the semiconductor device A10. A high voltage from an external source is applied between the first terminal 120 (the drain terminal) and the second terminal 220 (the source terminal). In response, the potential difference between the first terminal 120 (the drain terminal) and the third terminal 320 (the gate terminal) increases according to the high voltage applied.

The sealing resin 8 partly covers the first lead 1, the second lead 2, and the third lead 3, and entirely covers the semiconductor element 6 and the wires 71 and 72. The sealing resin 8 is made of a black epoxy resin, for example. The material of the sealing resin 8 is not specifically limited. The sealing resin 8 may be formed by transfer molding using a mold, for example.

The sealing resin 8 has a resin obverse surface 81, a resin reverse surface 82, a resin end surface 83, a resin first side surface 84, a resin second side surface 85, and a resin third side surface 86. The resin obverse surface 81 and the resin reverse surface 82 face away from each other in the z direction. The resin obverse surface 81 faces the z2 side in the z direction, and the resin reverse surface 82 faces the z1 side in the z direction. As shown in FIGS. 4, 6 and 7, the entire region of the mounting-portion reverse surface 112 of the first lead 1 is exposed from the resin reverse surface 82. The mounting-portion reverse surface 112 and the resin reverse surface 82 are flush with each other.

Each of the resin end surface 83 and the resin first side surface 84 is connected to the resin obverse surface 81 and the resin reverse surface 82. The resin end surface 83 and the resin first side surface 84 face away from each other in the x direction. The resin end surface 83 is located on the x1 side in the x direction and faces the x1 side in the x direction. The resin first side surface 84 is located on the x2 side in the x direction and faces the x2 side in the x direction. Each of the resin second side surface 85 and the resin third side surface 86 is connected to the resin obverse surface 81, the resin reverse surface 82, the resin end surface 83, and the resin first side surface 84. The resin second side surface 85 and the resin third side surface 86 face away from each other in the y direction. The resin second side surface 85 is located on the y1 side in the y direction and faces the y1 side in the y direction. The resin third side surface 86 is located on the y2 side in the y direction and faces the y2 side in the y direction.

Each of the resin end surface 83, the resin first side surface 84, the resin second side surface 85, and the resin third side surface 86 has a region that is connected to the resin obverse surface 81 and inwardly inclined toward the resin obverse surface 81. That is, of the sealing resin 8, the portion surrounded by the inclined regions connected to the resin obverse surface 81 is tapered so that the section along the x-y plane is gradually smaller with approach toward the resin obverse surface 81. Each of the resin end surface 83, the resin first side surface 84, the resin second side surface 85, and the resin third side surface 86 additionally has a region that is connected to the resin reverse surface 82 and inwardly inclined toward the resin reverse surface 82. That is, of the sealing resin 8, the portion surrounded by the inclined regions connected to the resin reverse surface 82 is tapered so that the section along the x-y plane is gradually smaller with approach toward the resin reverse surface 82. The shapes of the resin end surface 83, the resin first side surface 84, the resin second side surface 85, and the resin third side surface 86, however, are not specifically limited.

The resin end surface 83 faces in the direction in which the first terminal 120, the second terminal 220, and the third terminal 320 protrude. That is, the resin end surface 83 is the surface where the first terminal 120, the second terminal 220, and the third terminal 320 protrude. At the resin end surface 83 as shown in FIG. 5, the second terminal 220, the first terminal 120, and the third terminal 320 are spaced apart from each other in the y direction and arranged from the y1 side to the y2 side in the stated order. That is, at the resin end surface 83, the third terminal 320 is located on the side opposite the second terminal 220 in the y direction with respect to the first terminal 120. At the resin end surface 83, in addition, the first terminal 120 is spaced apart from the second terminal 220 and the third terminal 320 in the z direction, and the second terminal 220 and the third terminal 320 are located at the same position in the z direction. At the resin end surface 83, the first terminal 120 is located on the side of the resin reverse surface 82 in the z direction (the z2 side in the z direction) with respect to the second terminal 220 and the third terminal 320.

As shown in FIG. 5, the shortest distance (creepage distance) D between the first terminal 120 and the second terminal 220 along the resin end surface 83 is greater in this arrangement than in an arrangement where the first terminal 120 and the second terminal 220 are located at the same position in the z direction. Here, let Dy denote the separation distance in the y direction between the first terminal 120 and the second terminal 220 at the resin end surface 83, and Dz denote the separation distance in the z direction. When the first terminal 120 and the second terminal 220 are located at the same position in the z direction, the creepage distance between the first terminal 120 and the second terminal 220 along the resin end surface 83 is equal to the separation distance Dy between them. In contrast, the creepage distance D is as given by D=√(Dy²+Dz²). Similarly, the creepage distance between the first terminal 120 and the third terminal 320 along the resin end surface 83 is greater than in an arrangement where the first terminal 120 and the third terminal 320 are located at the position in the z direction.

The conductive member 5 is exposed from the resin reverse surface 82 and the resin end surface 83 but not from the resin obverse surface 81, the resin first side surface 84, the resin second side surface 85, and the resin third side surface 86.

In the present embodiment, the sealing resin 8 is formed with a resin through-hole 88. The resin through-hole 88 extends parallel to the z direction from the resin obverse surface 81 through to the resin reverse surface 82. The resin through-hole 88 is located at the center of the sealing resin 8 in the y direction and closer to the end on the x2 side in x direction (the upper side in FIG. 3) and has a circular shape as viewed in the z direction. In the present embodiment, the resin through-hole 88 has the same center as the mounting-portion through-hole 113. In addition, the resin through-hole 88 is smaller in diameter than the mounting-portion through-hole 113. Thus, as shown in FIGS. 3, 4 and 6, the resin through-hole 88 is contained inside the mounting-portion through-hole 113, and the entire inner wall of the resin through-hole 88 is formed by the sealing resin 8. In other words, the mounting portion 110 is not exposed at the inner wall of the resin through-hole 88. The resin through-hole 88 is provided for receiving, for example, a fastening member such as a screw to attach a heat dissipating member to the semiconductor device A10. When a heat dissipating member is attached to the mounting-portion reverse surface 112 via an electrically insulating sheet, heat of the semiconductor element 6 is released through the mounting portion 110 and the heat dissipating member.

Next, the effects of the semiconductor device A10 will be described.

According to the present embodiment, the first lead 1 includes the first terminal 120 protruding from the resin end surface 83. The second lead 2 includes the second terminal 220 protruding from the resin end surface 83. At the resin end surface 83, the first terminal 120 and the second terminal 220 are spaced apart from each other in the y direction and also in the z direction. As such, the creepage distance D between the first terminal 120 and the second terminal 220 along the resin end surface 83 is greater than in an arrangement where the first terminal 120 and the second terminal 220 are located at the same position in the z direction. The semiconductor device A10 can therefore prevent electrical discharges on the resin end surface 83 when a high voltage is applied between the first terminal 120 and the second terminal 220. In addition, the third lead 3 includes the third terminal 320 protruding from the resin end surface 83. At the resin end surface 83, the first terminal 120 and the third terminal 320 are spaced apart from each other in the y direction and also in the z direction. As such, the creepage distance between the first terminal 120 and the third terminal 320 along the resin end surface 83 is greater than in an arrangement where the first terminal 120 and the third terminal 320 are located at the same position in the z direction. The semiconductor device A10 can therefore prevent electrical discharges on the resin end surface 83 when a large potential difference is applied between the first terminal 120 and the third terminal 320. As described above, the semiconductor device A10 can achieve a higher dielectric strength.

According to the present embodiment, in addition, the second-pad-portion reverse surface 212 is exposed from the resin reverse surface 82. With this configuration, a heat dissipating member can be attached to the second-pad-portion reverse surface 212, so that the semiconductor device A10 can release heat of the semiconductor element 6. The sealing resin 8 is formed with the resin through-hole 88 extending parallel to the z direction. With this configuration, a fastening member, such as a screw, can be inserted into the resin through-hole 88, so that a heat dissipating member can be easily attached to the semiconductor device A10. In addition, the resin through-hole 88 has the same center as the mounting-portion through-hole 113 and a smaller diameter than the mounting-portion through-hole 113. Hence, the resin through-hole 88 is contained inside the mounting-portion through-hole 113, and the entire inner wall of the resin through-hole 88 is formed by the sealing resin 8. In other words, the mounting portion 110 is not exposed at the inner wall of the resin through-hole 88. This provides electrical insulation between the mounting portion 110 and the fastening member. According to the present embodiment, in addition, the mounting portion 110 has a greater thickness than the first terminal 120, the second lead 2, and the third lead 3. The semiconductor device A10 can therefore ensure that heat released from the semiconductor element 6 is efficiently absorbed by the mounting portion 110.

Although the present embodiment describes the case where the mounting portion 110 and the sealing resin 8 respectively include the mounting-portion through-hole 113 and the resin through-hole 88, the present disclosure is not limited thereto. The mounting portion 110 may not include a mounting-portion through-hole 113, and the sealing resin 8 may not include a resin through-hole 88. This applies to other embodiments and variations described below.

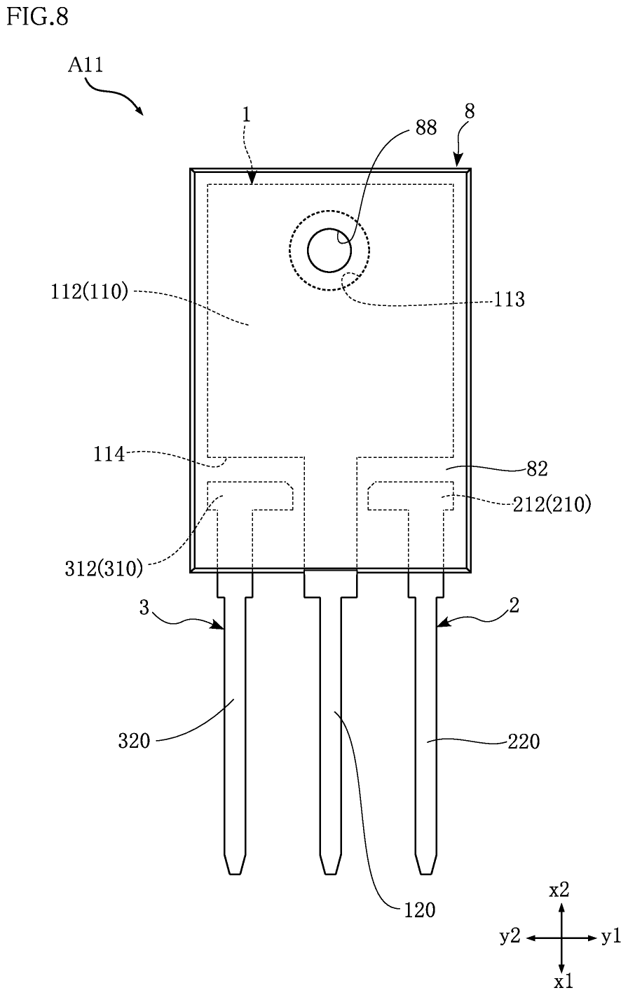

FIGS. 8 to 16 shows the first lead 1 according to variations of the first embodiment. In these figures, components that are identical or similar to those of the embodiment described above are given the same reference numerals, and descriptions of such components are omitted to avoid redundancy.

### First Variation:

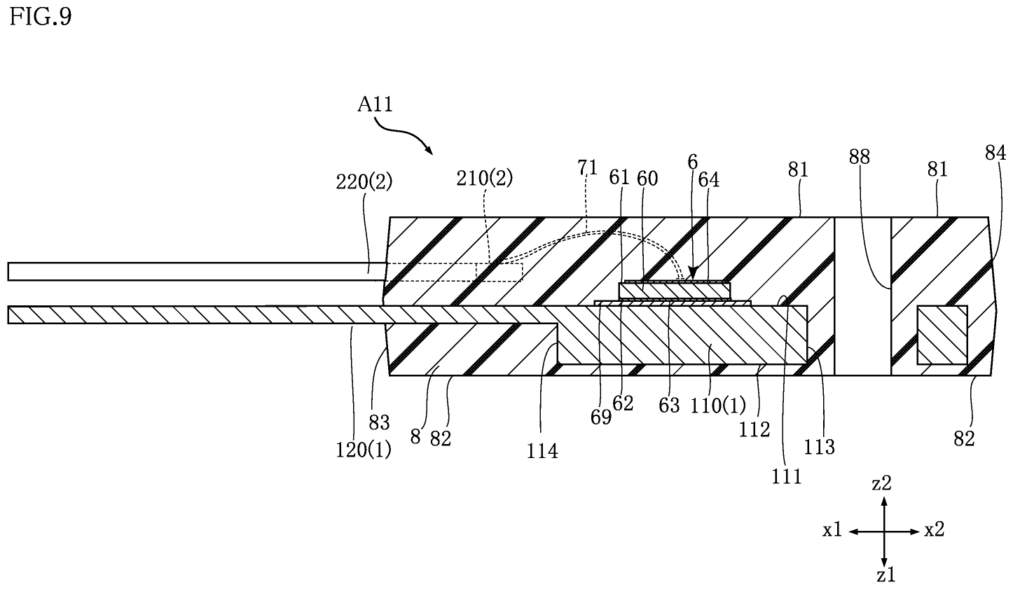

FIGS. 8 and 9 are views for illustrating a semiconductor device A11 according to a first variation of the first embodiment. FIG. 8 is a bottom view of the semiconductor device A11 and corresponds to FIG. 4. FIG. 9 is a sectional view of the semiconductor device A11 and corresponds to FIG. 6. In the semiconductor device A11, the mounting-portion reverse surface 112 is not exposed from the resin reverse surface 82 and covered with the sealing resin 8.

### Second Variation:

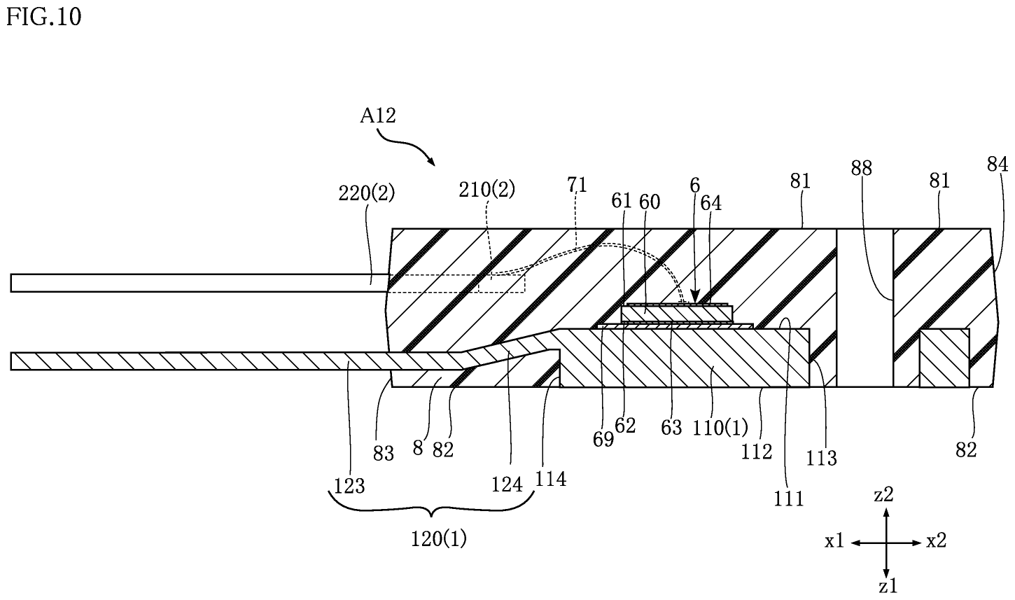

FIG. 10 is a sectional view of a semiconductor device A12 according to a second variation of the first embodiment and corresponds to FIG. 6. The semiconductor device A12 differs from the semiconductor device A10 in the shape of the first terminal 120. In the semiconductor device A12, the first terminal 120 includes a first straight portion 123 and a first connecting portion 124. The first straight portion 123 extends straight in the x direction and includes a portion covered with the sealing resin 8 and a portion protruding from the sealing resin 8. The first connecting portion 124 is connected to the first straight portion 123 and the mounting portion 110 to connect the first straight portion 123 and the mounting portion 110. The first connecting portion 124 is entirely covered with the sealing resin 8 and inclined relative to the mounting portion 110 and the first straight portion 123. The first straight portion 123 is located such that its surface facing the same side as the mounting-portion obverse surface 111 (the z2 side in the z direction) is located on the z1 side in the z direction with respect to the mounting-portion obverse surface 111. Hence, the first connecting portion 124 is inclined toward the z1 side in the z direction with approach toward the x1 side in the X direction. In this variation, the location of the first terminal 120 at the resin end surface 83 is closer to the z1 side in the z direction than that in the semiconductor device A10. Hence, as compared with the semiconductor device A10, the semiconductor device A12 can increase the creepage distance D between the first terminal 120 and the second terminal 220 along the resin end surface 83 and also increase the creepage distance between the first terminal 120 and the third terminal 320.

### Third Variation:

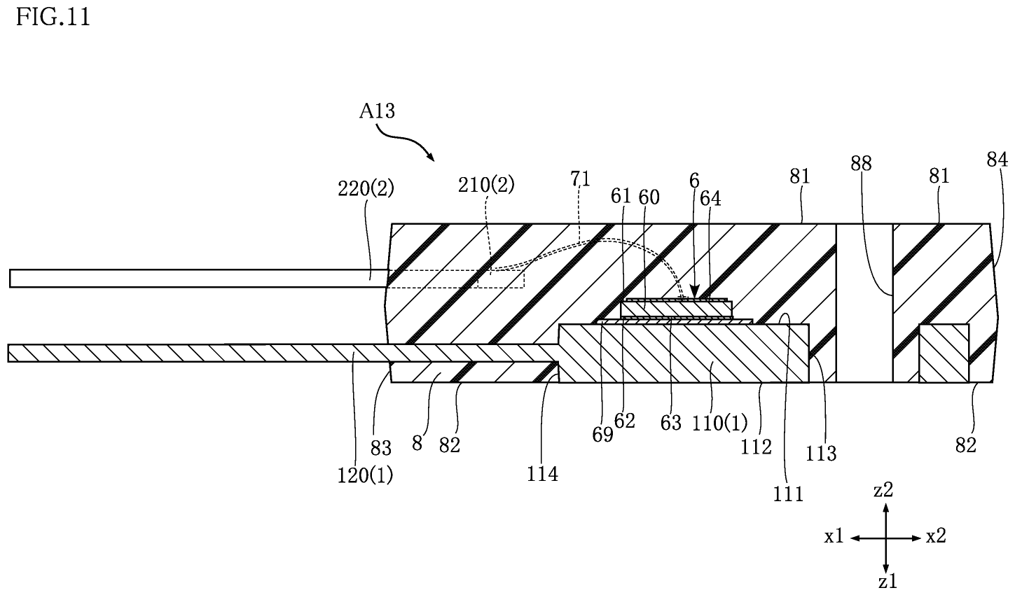

FIG. 11 is a sectional view of a semiconductor device A13 according to a third variation of the first embodiment and corresponds to FIG. 6. The semiconductor device A13 differs from the semiconductor device A10 in the position on the mounting portion 110 where the first terminal 120 is connected. In the semiconductor device A13, the first terminal 120 is connected to the mounting-portion end surface 114 at the center of the mounting-portion end surface 114 in both the y direction and the z direction as shown in FIG. 11. In this variation, the location of the first terminal 120 at the resin end surface 83 is closer to the z1 side in the z direction than that in the semiconductor device A10. Hence, as compared with the semiconductor device the A10, semiconductor device A13 can increase the creepage distance D between the first terminal 120 and the second terminal 220 along the resin end surface 83 and also increase the creepage distance between the first terminal 120 and the third terminal 320.

### Fourth Variation:

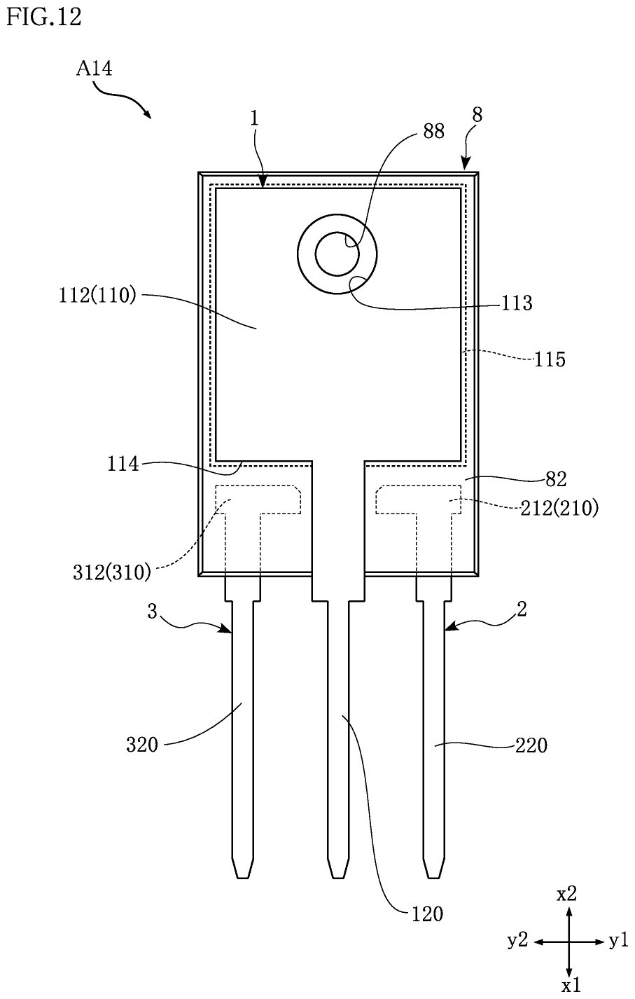

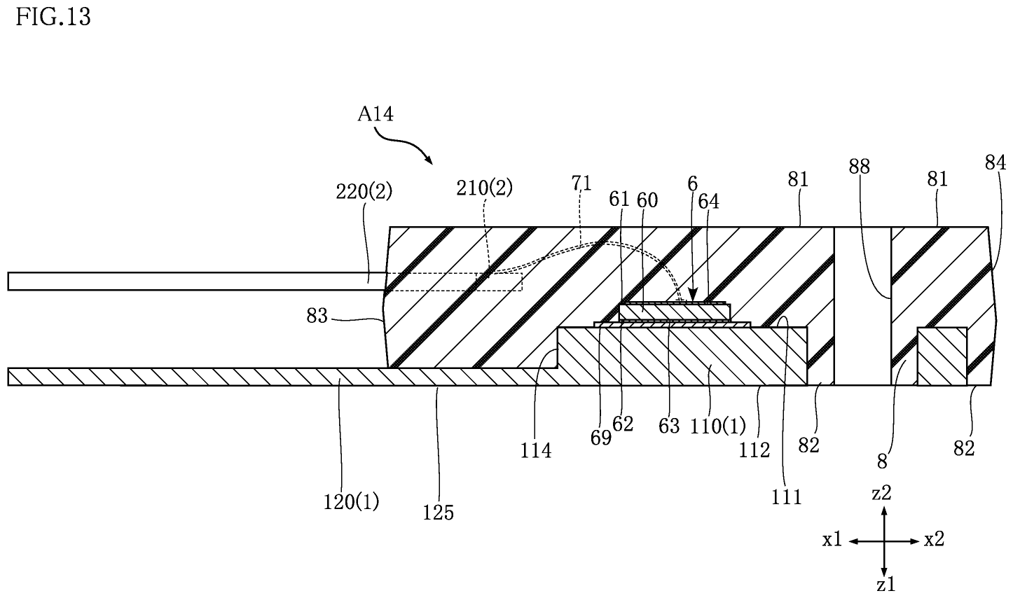

FIGS. 12 and 13 are views for illustrating a semiconductor device A14 according to a fourth variation of the first embodiment. FIG. 12 is a bottom view of the semiconductor device A14 and corresponds to FIG. 4. FIG. 13 is a sectional view of the semiconductor device A14 and corresponds to FIG. 6. The semiconductor device A14 differs from the semiconductor device A10 in the position where on the mounting portion 110 the first terminal 120 is connected. In the semiconductor device A14, the first terminal 120 is connected at the center of the mounting-portion end surface 114 in the y direction as shown in FIG. 12 to the end of the mounting-portion end surface 114 on the z1 side in the z direction as shown in FIG. 13. In this variation, the first-terminal reverse surface 125, which is the surface of the first terminal 120 facing the same side as the mounting-portion reverse surface 112 (the z1 side in the z direction), is flush with the mounting-portion reverse surface 112 and exposed from the resin reverse surface 82. In this variation, in addition, the mounting portion 110 is formed with a reverse-surface recess 115 along the outer edge of the mounting-portion reverse surface 112 as shown in FIG. 12. The reverse-surface recess 115 is recessed from the mounting-portion reverse surface 112 toward the mounting-portion obverse surface 111 and covered with the sealing resin 8. Although the mounting portion 110 may not include the reverse-surface recess 115, providing the reverse-surface recess 115 is preferable for preventing detachment of the first lead 1 from the sealing resin 8 toward the z1 side in the z direction. As shown in FIG. 13, the location of the first terminal 120 at the resin end surface 83 in this variation is closer to the z1 side in the z direction than that in the semiconductor device A10. Hence, as compared with the semiconductor device A10, the semiconductor device A14 can increase the creepage distance D between the first terminal 120 and the second terminal 220 along the resin end surface 83 and also increase the creepage distance between the first terminal 120 and the third terminal 320.

### Fifth Variation:

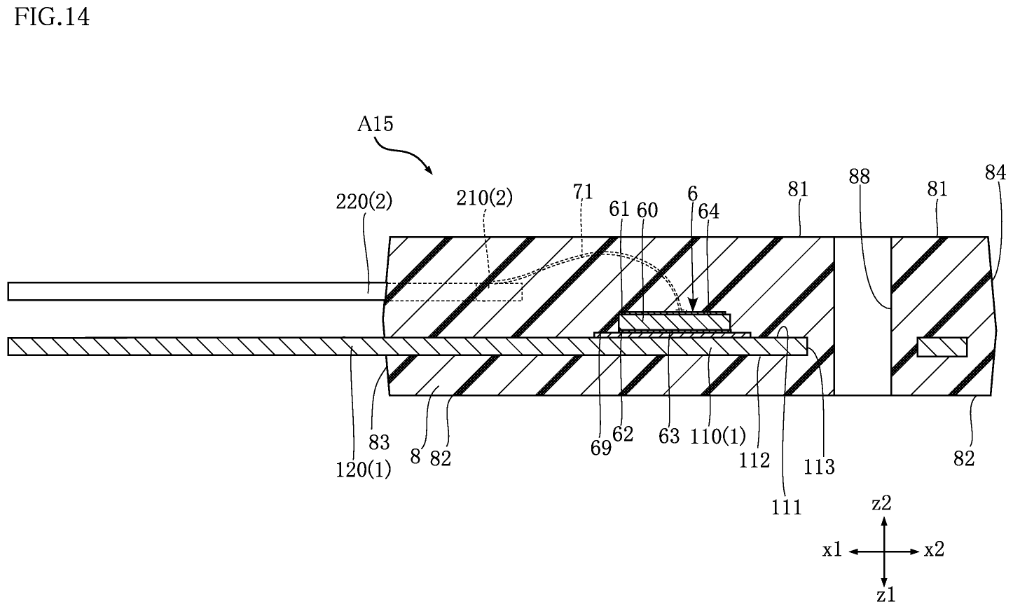

FIG. 14 is a sectional view of a semiconductor device A15 according to a fifth variation of the first embodiment and corresponds to FIG. 6. The semiconductor device A15 differs from the semiconductor device A10 in the thickness of the mounting portion 110. In the semiconductor device A15, the mounting portion 110 has the same thickness as the first terminal 120. Note that the position of the mounting-portion obverse surface 111 in the z direction in this variation is the same as that in the semiconductor device A10.

### Sixth Variation:

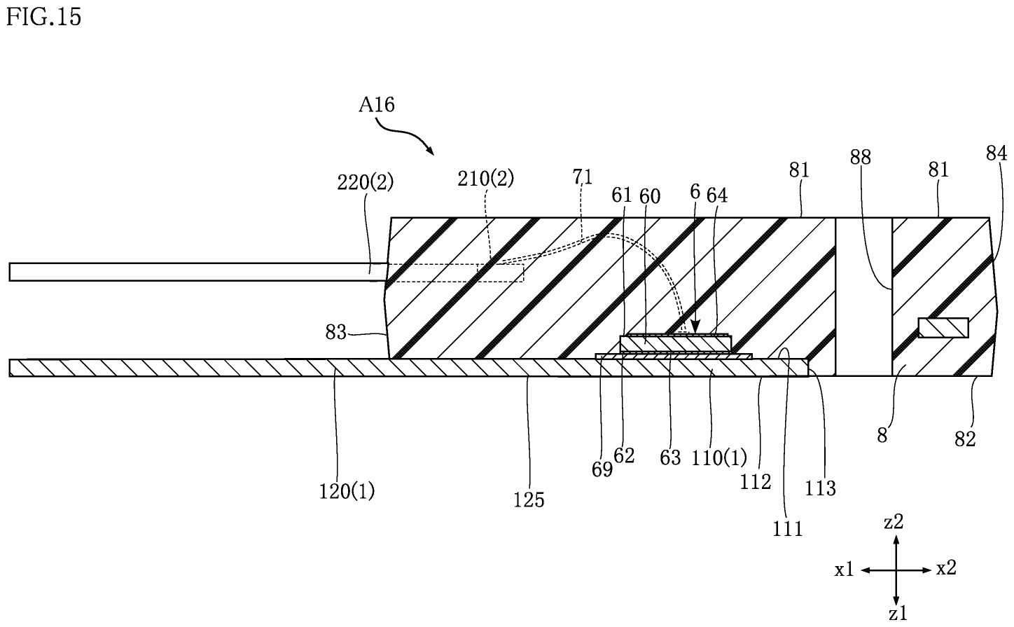

FIG. 15 is a sectional view of a semiconductor device A16 according to a sixth variation of the first embodiment and corresponds to FIG. 6. The semiconductor device A16 differs from the semiconductor device A15 in the position of the first lead 1 in the z direction. In the semiconductor device A16, the mounting portion 110 has the same thickness as the first terminal 120. Unlike the semiconductor device A15, the mounting-portion reverse surface 112 is exposed from the resin reverse surface 82. In addition, the mounting-portion obverse surface 111 and the first terminal 120 are located differently in the z direction than those of the semiconductor device A15. In the semiconductor device A16, the first-terminal reverse surface 125 is flush with the mounting-portion reverse surface 112 and exposed from the resin reverse surface 82. As in the fourth variation (see FIG. 12), the mounting portion 110 of this variation is preferably formed with the reverse-surface recess 115 along the outer edge of the mounting-portion reverse surface 112. In this variation, the location of the first terminal 120 at the resin end surface 83 is closer to the z1 side in the z direction than that in the semiconductor device A10. Hence, as compared with then semiconductor device A10, the semiconductor device A16 can increase the creepage distance D between the first terminal 120 and the second terminal 220 along the resin end surface 83 and also increase the creepage distance between the first terminal 120 and the third terminal 320.

### Seventh Variation:

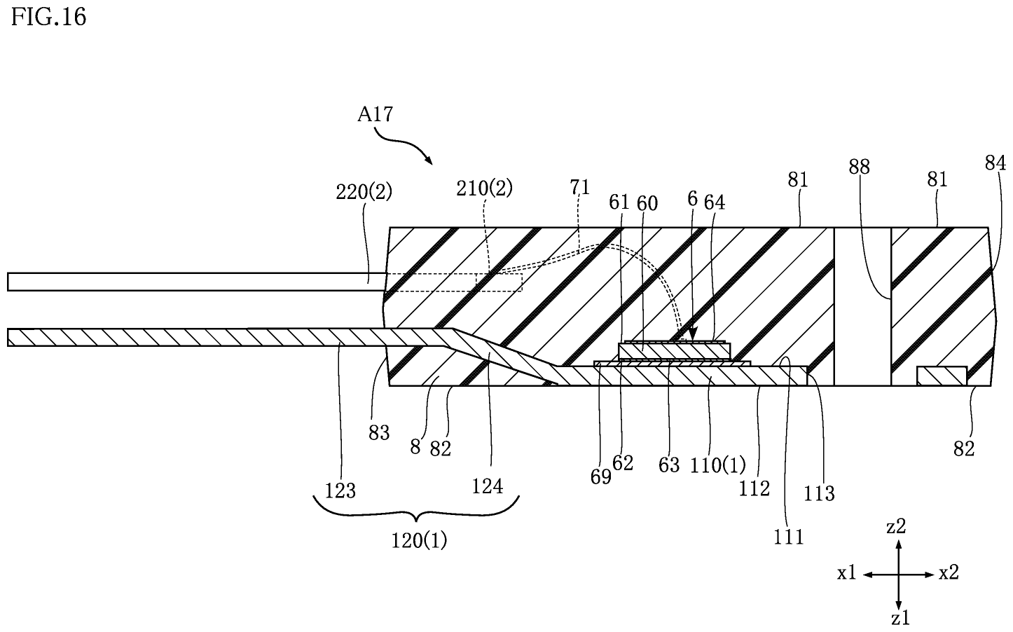

FIG. 16 is a sectional view of a semiconductor device A17 according to a seventh variation of the first embodiment and corresponds to FIG. 6. The semiconductor device A17 differs from the semiconductor device A16 in the shape of the first terminal 120. In the semiconductor device A17, the mounting portion 110 has the same thickness as the first terminal 120. In addition, the mounting-portion reverse surface 112 is exposed from the resin reverse surface 82. The first terminal 120 includes a first straight portion 123 and a first connecting portion 124. The first straight portion 123 extends straight in the x direction and includes a portion covered with the sealing resin 8 and a portion protruding from the sealing resin 8. The first connecting portion 124 is connected to the first straight portion 123 and the mounting portion 110 to connect the first straight portion 123 and the mounting portion 110. The first connecting portion 124 is entirely covered with the sealing resin 8 and inclined relative to the mounting portion 110 and the first straight portion 123. The first straight portion 123 is located on the z2 side in the z direction with respect to the mounting portion 110. Hence, the first connecting portion 124 is inclined toward the z2 side in the z direction with approach toward the x1 side in the x direction. Thus, the mounting-portion reverse surface 112 is exposed from the resin reverse surface 82, but the first connecting portion 124 and a portion of the first straight portion 123 are covered with the sealing resin 8. With this configuration, the first lead 1 having the mounting portion 110 and the first terminal 120 of the same thickness can achieve both the heat dissipation and the prevention of detachment.

### Eighth Variation:

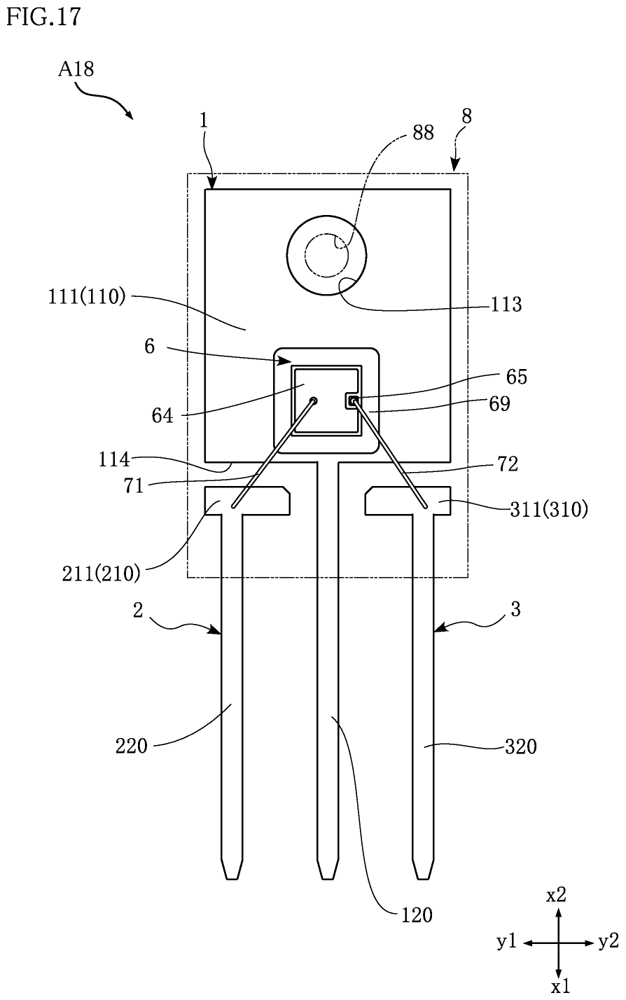

FIG. 17 is a plan view of a semiconductor device A18 according to an eighth variation of the first embodiment and corresponds to FIG. 3. For convenience, FIG. 17 shows the sealing resin 8 as transparent and indicates the outline of the sealing resin 8 with an imaginary line (two-dot-dash line). The semiconductor device A18 differs from the semiconductor device A10 in the shapes of the first terminal 120, the second terminal 220, and the third terminal 320. In the semiconductor device A18, each of the first terminal 120, the second terminal 220, and the third terminal 320 does not have a wider portion. In other words, each of the first terminal 120, the second terminal 220, and the third terminal 320 has a uniform width throughout the portion protruding from the sealing resin 8. Alternatively, this variation may employ the first terminal 120, the second terminal 220, and the third terminal 320 having shapes similar to those of the semiconductor device A10, and the entire wider width portions of the first terminal 120, the second terminal 220, and the third terminal 320 are covered with the sealing resin 8. In this example, the first terminal 120, the second terminal 220, and the third terminal 320 have a uniform width throughout the portions protruding from the sealing resin 8, so that the resulting semiconductor device is identical in appearance to the semiconductor device A10.

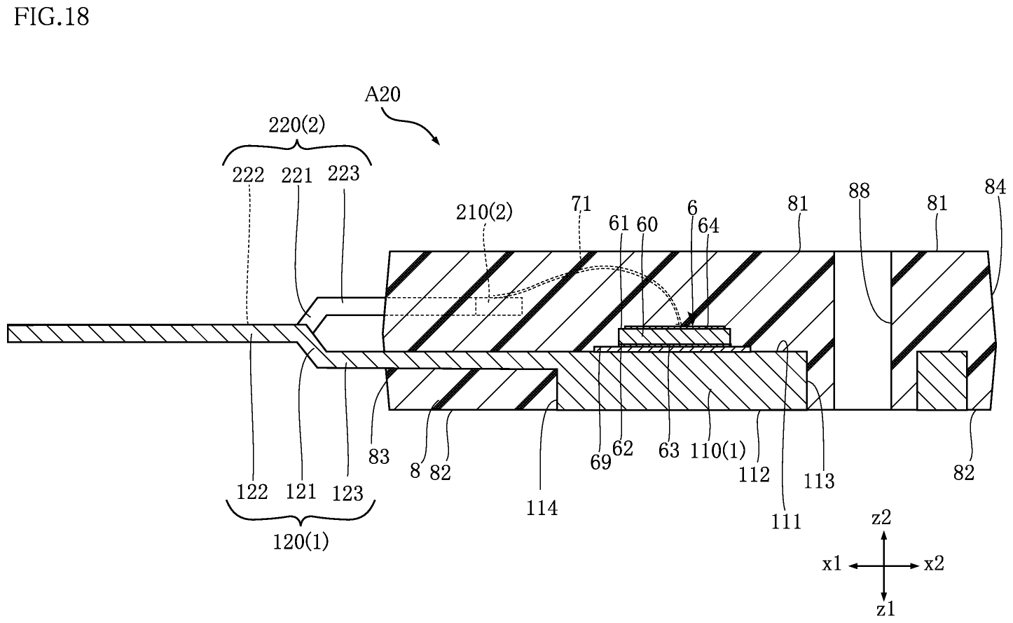

FIGS. 18 to 32 shown other embodiments of the present disclosure. In these figures, components that are identical or similar to those of the embodiment described above are given the same reference numerals, and descriptions of such components are omitted to avoid redundancy.

### Second Embodiment

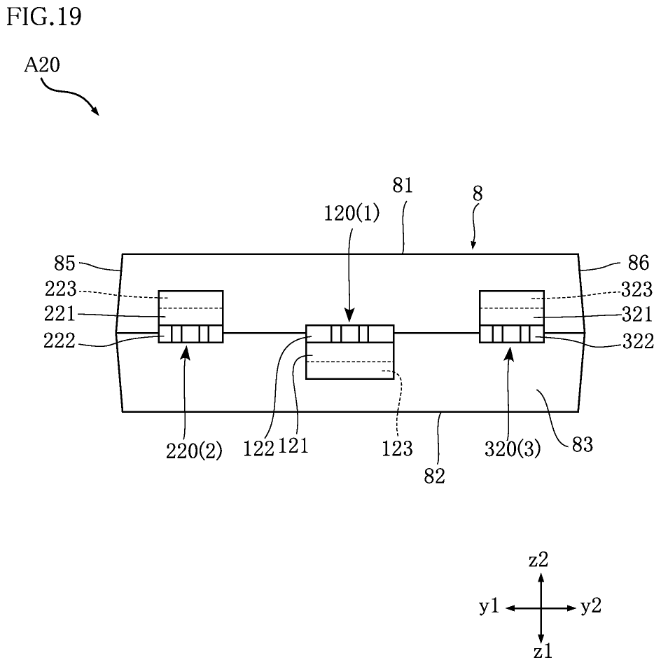

FIGS. 18 and 19 views for illustrating a are semiconductor device A20 according to a second embodiment of the present disclosure. FIG. 18 is a sectional view of the semiconductor device A20 and corresponds to FIG. 6. FIG. 19 is a front view of the semiconductor device A20 and corresponds to FIG. 5. The semiconductor device A20 of the present embodiment differs from the semiconductor device A10 of the first embodiment in the shapes of the first terminal 120, the second terminal 220, and the third terminal 320 in the portions protruding from the sealing resin 8. With respect to the other configurations and operations, the present embodiment is similar to the first embodiment. The present embodiment may be combined with any variation of the first embodiment.

In the present embodiment, the first terminal 120 includes a first straight portion 123, a first bent portion 121, and a first tip portion 122. As shown in FIG. 18, the first straight portion 123 extends straight in the x direction and includes a portion covered with the sealing resin 8 and a portion protruding from the sealing resin 8. The first bent portion 121 extends from the end of the first straight portion 123 on the x1 side in the x direction and forms a bend. The first tip portion 122 extends straight in the x direction from the end of the first bent portion 121 on the x1 side in the x direction. The first bent portion 121 and the first tip portion 122 are exposed from the sealing resin 8. In the present embodiment, the first bent portion 121 includes a portion inclined relative to the first tip portion 122 and the first straight portion 123. The first tip portion 122 is located on the z2 side in the z direction with respect to the first straight portion 123, so that the first bent portion 121 is inclined toward the z2 side in the z direction with approach toward the x1 side in the x direction.

Further, the second terminal 220 includes a second straight portion 223, a second bent portion 221, and a second tip portion 222. As shown in FIG. 18, the second straight portion 223 extends straight in the x direction and includes a portion covered with the sealing resin 8 and a portion protruding from the sealing resin 8. The second bent portion 221 extends from the end of the second straight portion 223 on the x1 side in the x direction and forms a bend. The second tip portion 222 extends straight in the x direction from the end of the second bent portion 221 on the x1 side in the x direction. The second bent portion 221 and the second tip portion 222 are exposed from the sealing resin 8. In the present embodiment, the second bent portion 221 includes a portion inclined relative to the second tip portion 222 and the second straight portion 223. The second tip portion 222 is located on the z1 side in the z direction with respect to the second straight portion 223, so that the second bent portion 221 is inclined toward the z1 side in the z direction with approach toward the x1 side in the x direction.

Further, the third terminal 320 includes a third straight portion 323, a third bent portion 321, and a third tip portion 322. Although not shown in FIG. 18, the third straight portion 323 extends straight in the x direction and includes a portion covered with the sealing resin 8 and a portion protruding from the sealing resin 8. The third bent portion 321 extends from the end of the third straight portion 323 on the x1 side in the x direction and forms a bend. The third tip portion 322 extends straight in the x direction from the end of the third bent portion 321 on the x1 side in the x direction. The third bent portion 321 and the third tip portion 322 are exposed from the sealing resin 8. In the present embodiment, the third bent portion 321 includes a portion inclined relative to the third tip portion 322 and the third straight portion 323. The third tip portion 322 is located on the z1 side in the z direction with respect to the third straight portion 323, so that the third bent portion 321 is inclined toward the z1 side in the z direction with approach toward the x1 side in the x direction.

As shown in FIG. 19, although the first straight portion 123, the second straight portion 223, and the third straight portion 323 are spaced apart from each other in the z direction, the first tip portion 122, the second tip portion 222, and the third tip portion 322 coincide in position in the z direction.

In the present embodiment, at the resin end surface 83, the first terminal 120 (the first straight portion 123) and the second terminal 220 (the second straight portion 223) are spaced apart from each other in the y direction and also in the z direction. The creepage distance D between the first terminal 120 and the second terminal 220 along the resin end surface 83 is thus greater than the creepage distance between two terminals located at the same position in the z direction. Further, at the resin end surface 83, the first terminal 120 (the first straight portion 123) and the third terminal 320 (the third straight portion 323) are spaced apart from each other in the y direction and also in the z direction. The creepage distance between the first terminal 120 and the third terminal 320 along the resin end surface 83 is thus greater than the creepage distance between two terminals located at the same position in the z direction. With the configurations described above, the semiconductor device A20 can achieve a higher dielectric strength. In addition, the semiconductor device A20 has a configuration in common with the semiconductor device A10 and thus achieves the same effect as the semiconductor device A10. In addition, the semiconductor device A20 has the first tip portion 122, the second tip portion 222, and the third tip portion 322 that coincide in position in the z direction and thus is interchangeable with a conventional semiconductor device having the first lead 1, the second lead 2, and the third lead 3 that coincide in position in the z direction.

Although the present embodiment describes the case where the first bent portion 121 include a portion inclined relative to the first tip portion 122 and the first straight portion 123, the present disclosure is not limited thereto. The first bent portion 121 may include a portion orthogonal to the first tip portion 122 and the first straight portion 123. That is, the first lead 1 may have a crank-shape in the first bent portion 121. In another example, the first lead 1 may have an S-shape in the first bent portion 121. The same applies to the second lead 2 and the third lead 3.

### First Variation:

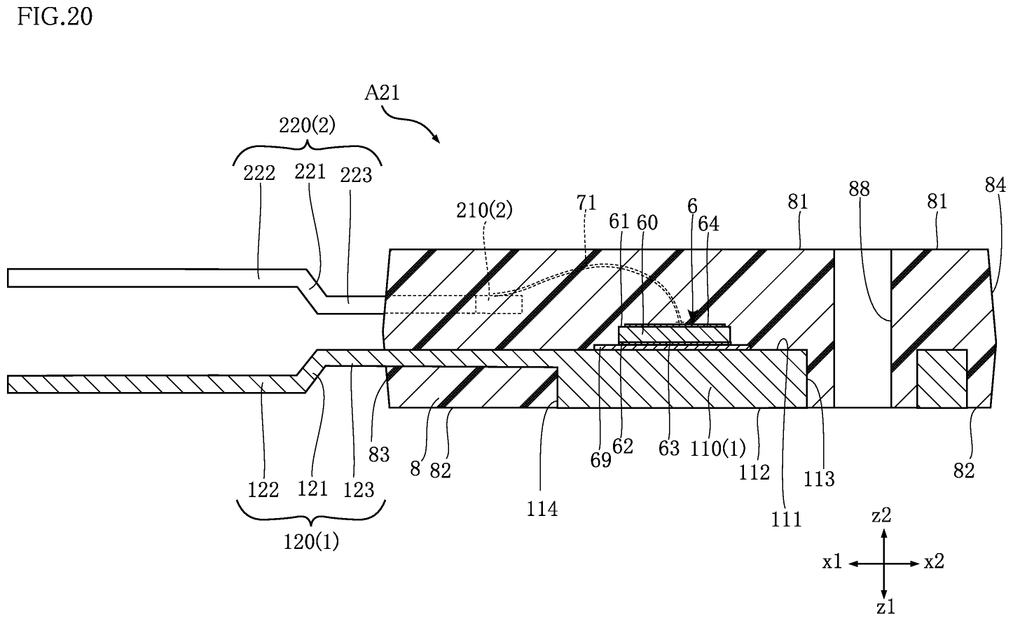

FIG. 20 is a sectional view of a semiconductor device A21 according to a first variation of the second embodiment and corresponds to FIG. 6. In the semiconductor device A21, the first tip portion 122 is located on the z1 side in the z direction with respect to the first straight portion 123, and the second tip portion 222 is located on the z2 side in the z direction with respect to the second straight portion 223, and the third tip portion 322 is located on the z2 side in the z direction with respect to the third straight portion 323. In other words, the separation distance between first tip portion 122 and each of the second tip portion 222 and the third tip portion 322 in the z direction is greater than the corresponding separation distance at the resin end surface 83.

### Third Embodiment

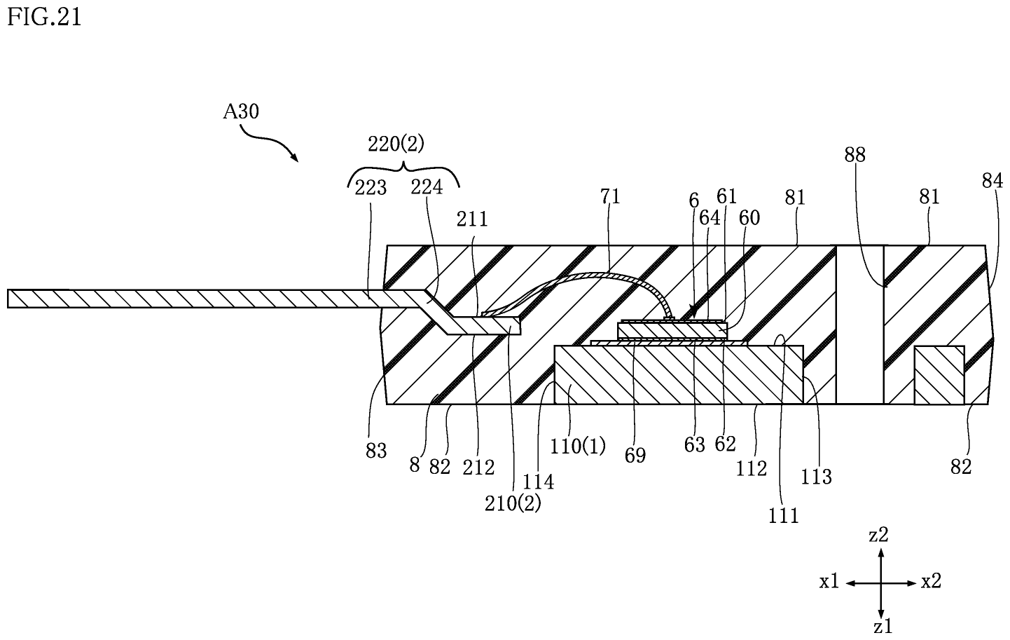

FIG. 21 is a view for illustrating a semiconductor device A30 according to a third embodiment. FIG. 21 is a sectional view of the semiconductor device A30 and corresponds to FIG. 7. The semiconductor device A30 of the present embodiment differs from the semiconductor device A10 of the first embodiment in the shapes of the second terminal 220 and the third terminal 320 in the portions covered with the sealing resin 8. With respect to the other configurations and operations, the present embodiment is similar to the first embodiment. The present embodiment may be combined with any variation of the first and second embodiments.

In the present embodiment, the second terminal 220 includes a second straight portion 223 and a second connecting portion 224. The second straight portion 223 extends straight in the x direction and includes a portion covered with the sealing resin 8 and a portion protruding from the sealing resin 8. The second connecting portion 224 is connected to the second straight portion 223 and the second pad portion 210 to connect the second straight portion 223 and the second pad portion 210. The second connecting portion 224 is entirely covered with the sealing resin 8 and inclined relative to the second pad portion 210 and the second straight portion 223. In the present embodiment, the second pad portion 210 is located on the side of the resin reverse surface 82 (the z1 side in the z direction) with respect to the second straight portion 223. Hence, the second connecting portion 224 is inclined toward the z2 side in the z direction with approach toward the x1 side in the x direction.

Although not shown in FIG. 21, the third terminal 320 includes a third straight portion 323 and a third connecting portion 324. The third straight portion 323 extends straight in the x direction and includes a portion covered with the sealing resin 8 and a portion protruding from the sealing resin 8. The third connecting portion 324 is connected to the third straight portion 323 and the third pad portion 310 to connect the third straight portion 323 and the third pad portion 310. The third connecting portion 324 is entirely covered with the sealing resin 8 and inclined relative to the third pad portion 310 and the third straight portion 323. In the present embodiment, the third pad portion 310 is located on the side of the resin reverse surface 82 (the z1 side in the z direction) with respect to the third straight portion 323. Hence, the third connecting portion 324 is inclined toward the z2 side in the z direction with approach toward the x1 side in the x direction.

In the present embodiment, the first terminal 120 and the second terminal 220 (the second straight portion 223) at the resin end surface 83 are spaced apart from each other in the y direction and also in the z direction. The creepage distance D between the first terminal 120 and the second terminal 220 along the resin end surface 83 is thus greater than the creepage distance between two terminals located at the same position in the z direction. Further, the first terminal 120 and the third terminal 320 (the third straight portion 323) at the resin end surface 83 are spaced apart from each other in the y direction and also in the z direction. The creepage distance between the first terminal 120 and the third terminal 320 along the resin end surface 83 is thus greater than the creepage distance between two terminals located at the same position in the z direction. With the configurations described above, the semiconductor device A30 can achieve a higher dielectric strength. Further, the semiconductor device A30 has a configuration in common with the semiconductor device A10 and thus achieves the same effect as the semiconductor device A10.

In the present embodiment, in addition, the second pad portion 210 is located on the side of the resin reverse surface 82 (the z1 side in the z direction) with respect to the second straight portion 223. Hence, the second-pad-portion obverse surface 211 is located closer to the z1 side in the z direction than that in the semiconductor device A10. Consequently, as compared with the configuration of the semiconductor device A10, the highest point of the wire 71 bonded to the second-pad-portion obverse surface 211 is located closer to the z1 side in the z direction. Further, the third pad portion 310 is located on the side of the resin reverse surface 82 (the z1 side in the z direction) with respect to the third straight portion 323. That is, the third-pad-portion obverse surface 311 is located closer to the z1 side in the z direction than that in the semiconductor device A10. Consequently, as compared with the configuration of the semiconductor device A10, the highest point of the wire 72 bonded to the third-pad-portion obverse surface 311 is located closer to the z1 side in the z direction. This configuration ensures that the wires 71 and 72 are not exposed from the sealing resin 8. Additionally, this configuration allows the sealing resin 8 to be more compact in thickness (a length in the z direction) than the configuration of the semiconductor device A10.

### Fourth Embodiment

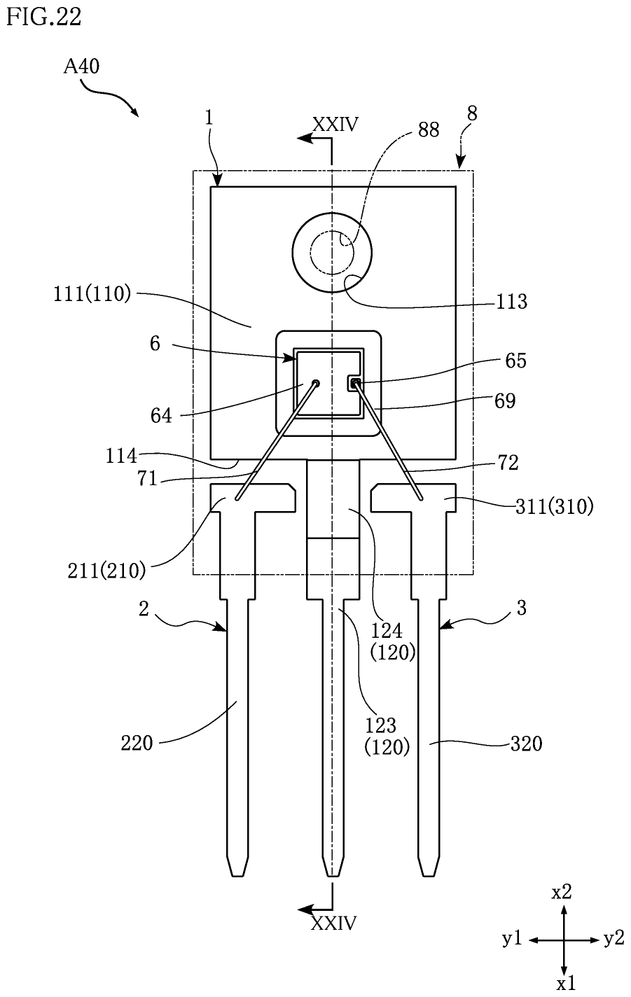

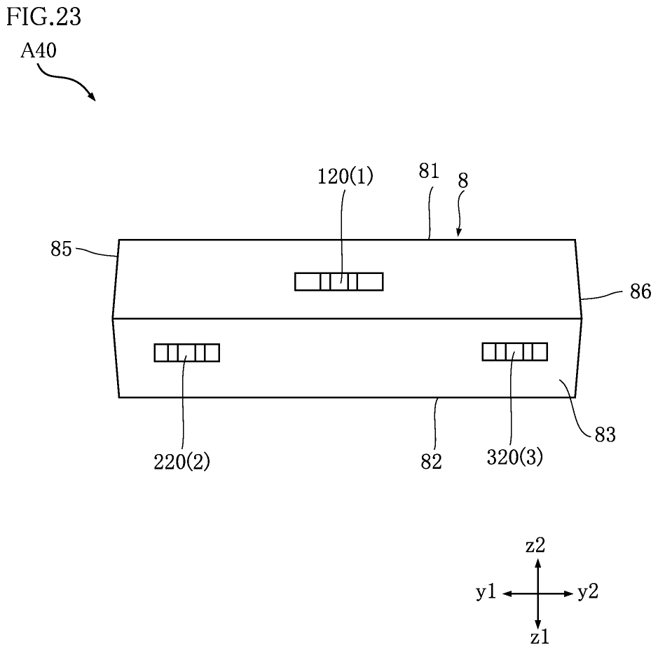

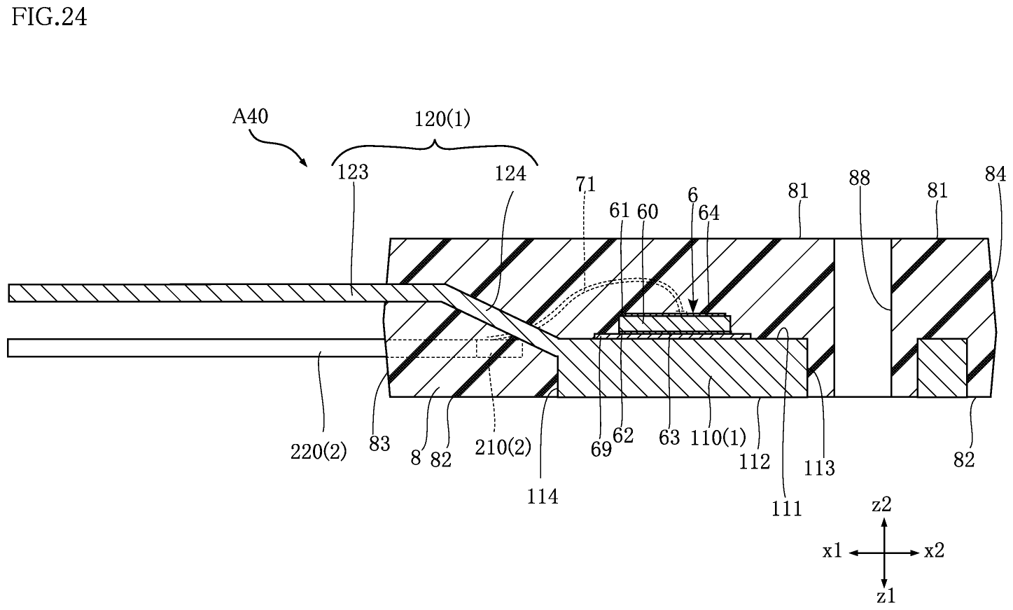

FIGS. 22 to 24 are views for illustrating a semiconductor device A40 according to a fourth embodiment. FIG. 22 is a plan view of the semiconductor device A40 and corresponds to FIG. 3. For convenience, FIG. 22 shows the sealing resin 8 as transparent and indicates the outline of the sealing resin 8 with an imaginary line (two-dot-dash line). FIG. 23 is a front view of the semiconductor device A40 and corresponds to FIG. 5. FIG. 24 is a sectional view taken along line XXIV-XXIV in FIG. 22. The semiconductor device A40 of the present embodiment differs from the semiconductor device A10 of the first embodiment in the positions of the first terminal 120, the second terminal 220, and the third terminal 320 in the z direction at the resin end surface 83. With respect to the other configurations and operations, the present embodiment is similar to the first embodiment. The present embodiment may be combined with any variation of the first to third embodiments.

In the present embodiment, the first terminal 120 includes a first straight portion 123 and a first connecting portion 124. The first straight portion 123 extends straight in the x direction and includes a portion covered with the sealing resin 8 and a portion protruding from the sealing resin 8. The first connecting portion 124 is connected to the first straight portion 123 and the mounting portion 110 to connect the first straight portion 123 and the mounting portion 110. The first connecting portion 124 is entirely covered with the sealing resin 8 and inclined relative to the mounting portion 110 and the first straight portion 123. The first straight portion 123 of this embodiment has the same position in the z direction as the second terminal 220 and the third terminal 320 of the semiconductor device A10 of the first embodiment. Hence, the first connecting portion 124 is inclined toward the z2 side in the z direction with approach toward the x1 side in the x direction. In the present embodiment, in addition, the second lead 2 (the second terminal 220) and the third lead 3 (the third terminal 320) also have the same position in the z direction as the first terminal 120 of the semiconductor device A10 in the first embodiment. Hence, at the resin end surface 83, the first terminal 120 (the first straight portion 123) is located on the side of the resin obverse surface 81 (the z2 side in the z direction) with respect to the second terminal 220 and the third terminal 320 in the z direction.

In the present embodiment, the first terminal 120 (the first straight portion 123) and the second terminal 220 at the resin end surface 83 are spaced apart from each other in the y direction and also in the z direction. The creepage distance D between the first terminal 120 and the second terminal 220 along the resin end surface 83 is thus greater than the creepage distance between two terminals located at the same position in the z direction. Similarly, the first terminal 120 (the first straight portion 123) and the third terminal 320 at the resin end surface 83 are spaced apart from each other in the y direction and also in the z direction. The creepage distance between the first terminal 120 and the third terminal 320 along the resin end surface 83 is thus greater than the creepage distance between two terminals located at the same position in the z direction. With the configurations described above, the semiconductor device A40 can achieve a higher dielectric strength. In addition, the semiconductor device A40 has a configuration in common with the semiconductor device A10 and thus achieves the same effect as the semiconductor device A10.

Further, the second lead 2 (the second pad portion 210) of this embodiment is located closer to the resin reverse surface 82 (the z1 side in the z direction) than that of the semiconductor device A10 of the first embodiment. Consequently, as compared with the configuration of the semiconductor device A10, the highest point of the wire 71 bonded to the second-pad-portion obverse surface 211 is located closer to the z1 side in the z direction. In addition, the third lead 3 (the third pad portion 310) of this embodiment is located closer to the resin reverse surface 82 (the z1 side in the z direction) than that of the semiconductor device A10. Consequently, as compared with the configuration of the semiconductor device A10, the highest point of the wire 72 bonded to the third-pad-portion obverse surface 311 is located closer to the z1 side in the z direction. This configuration ensures that the wires 71 and 72 are not exposed from the sealing resin 8. Additionally, this configuration allows the sealing resin 8 to be more compact in thickness (a length in the z direction) than the configuration of the semiconductor device A10.

### Fifth Embodiment

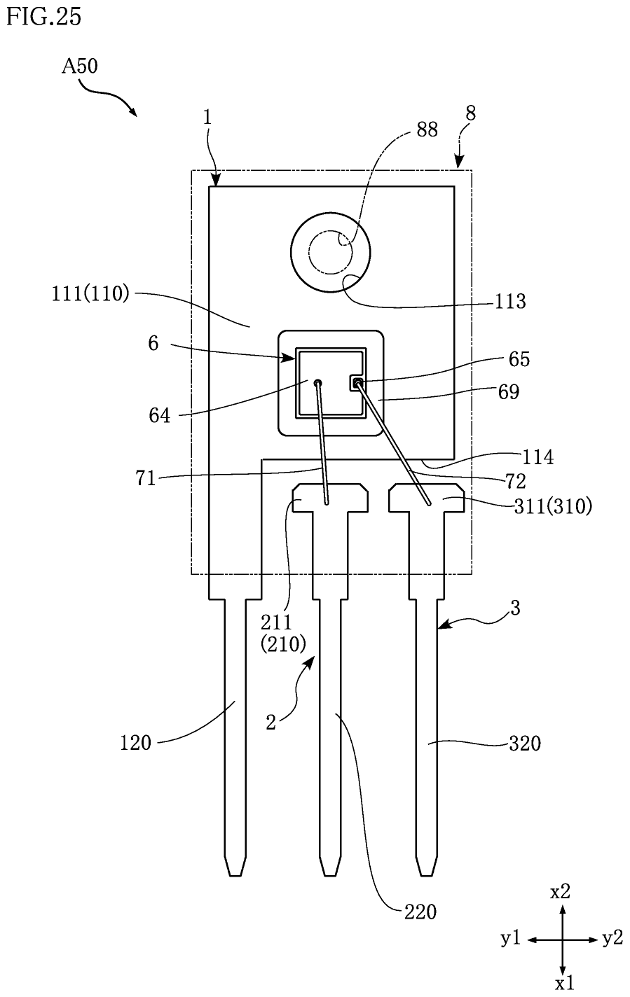

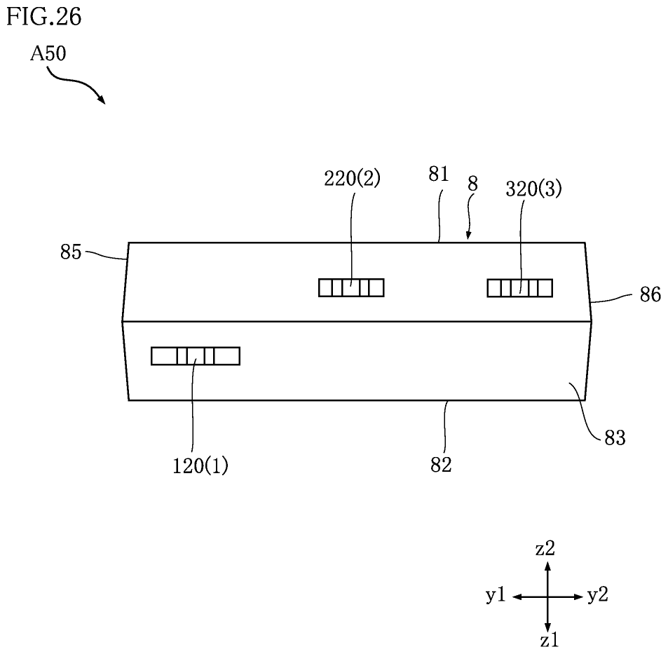

FIGS. 25 and 26 are views illustrating for a semiconductor device A50 according to a fifth embodiment. FIG. 25 is a plan view of the semiconductor device A50 and corresponds to FIG. 3. For convenience, FIG. 25 shows the sealing resin 8 as transparent and indicates the outline of the sealing resin 8 with an imaginary line (two-dot-dash line). FIG. 26 is a front view of the semiconductor device A50 and corresponds to FIG. 5. The semiconductor device A50 of the present embodiment differs from the semiconductor device A10 of the first embodiment in the positions of the first terminal 120 and the second terminal 220 in the y direction. With respect to the other configurations and operations, the present embodiment is similar to the first embodiment. The present embodiment may be combined with any variation of the first to fourth embodiments.

As shown in FIG. 25, the first terminal 120 of the present embodiment is connected to the end of the mounting-portion end surface 114 on the y1 side in the y direction. Also as shown in FIG. 25, the second lead 2 is located on the y2 side of the first terminal 120 in the y direction. In other words, the positions of the first terminal 120 and the second terminal 220 in the semiconductor device A50 are opposite in the y direction from those in the semiconductor device A10.

In the present embodiment, the first terminal 120 and the second terminal 220 at the resin end surface 83 are spaced apart from each other in the y direction and also in the z direction. The creepage distance D between the first terminal 120 and the second terminal 220 along the resin end surface 83 is thus greater than the creepage distance between two terminals located at the same position in the z direction. With the configurations described above, the semiconductor device A50 can achieve a higher dielectric strength. Note that the third terminal 320 is widely spaced apart from the first terminal 120 at resin end surface 83. Hence, the creepage distance between the first terminal 120 and the third terminal 320 along the resin end surface 83 is sufficiently large and will not present a problem. In addition, the semiconductor device A50 has a configuration in common with the semiconductor device A10 and thus achieves the same effect as the semiconductor device A10.

### First Variation:

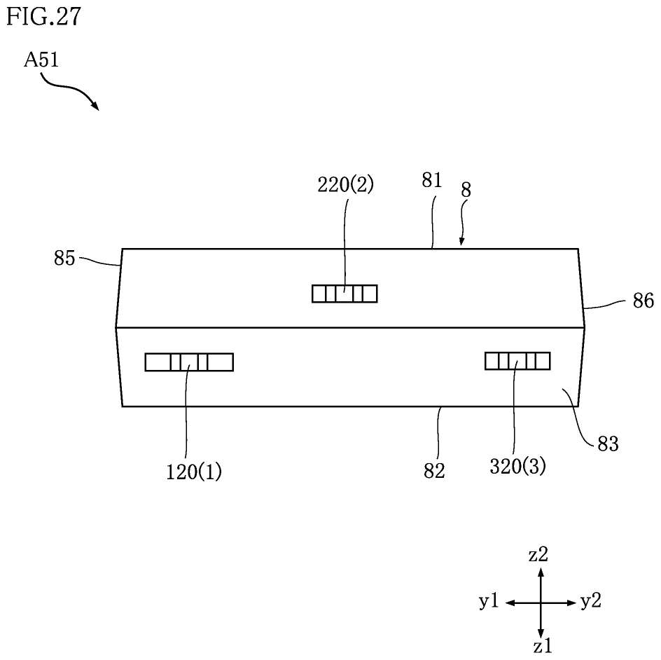

FIG. 27 is a front view of a semiconductor device A51 according to a first variation of the fifth embodiment and corresponds to FIG. 5. For the semiconductor device A51, the third lead 3 is located at the same position as the first terminal 120 in the z direction. That is, at the resin end surface 83, the third terminal 320 is widely spaced apart from the first terminal 120. This arrangement provides a sufficient creepage distance and allows flexibility in determining the position of the third lead 3 in the Z direction.

### Sixth Embodiment

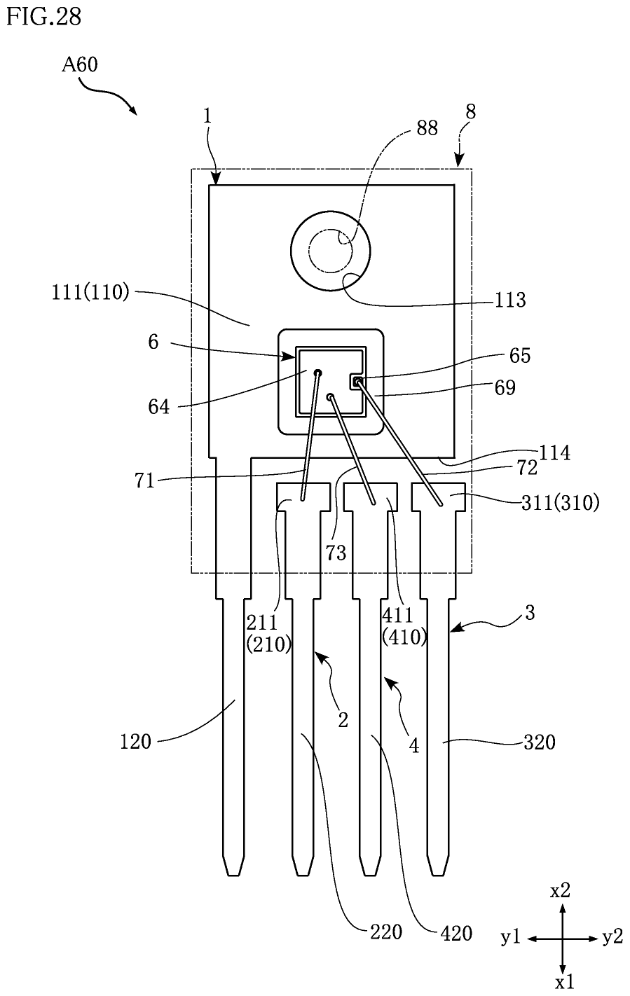

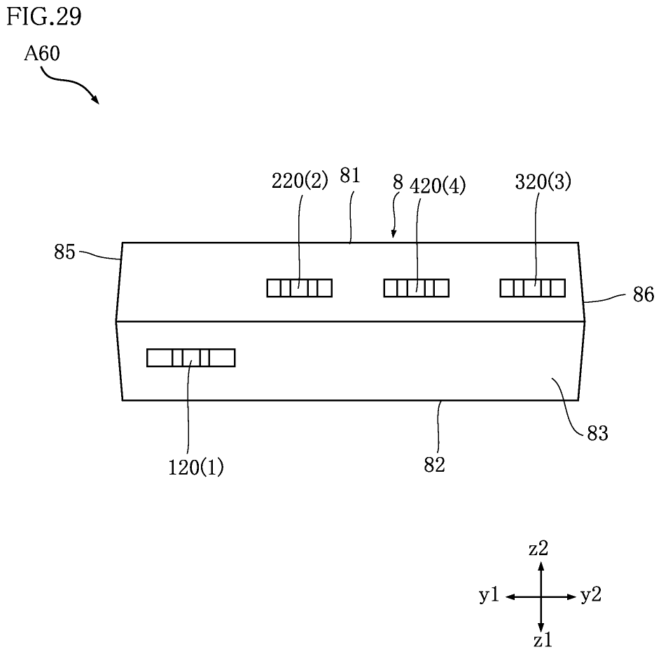

FIGS. 28 and 29 are views for illustrating a semiconductor device A60 according to a sixth embodiment. FIG. 28 is a plan view of the semiconductor device A60 and corresponds to FIG. 3. For convenience, FIG. 28 shows the sealing resin 8 as transparent and indicates the outline of the sealing resin 8 with an imaginary line (two-dot-dash line). FIG. 29 is a front view of the semiconductor device A60 and corresponds to FIG. 5. Different from the semiconductor device A50 of the fifth embodiment, the semiconductor device A60 of the present embodiment additionally includes a fourth lead 4. With respect to the other configurations and operations, the present embodiment is similar to the fifth embodiment. The present embodiment may be combined with any variation of the first to fifth embodiments.

The semiconductor device A60 of the present embodiment additionally includes the fourth lead 4 and a wire 73. The fourth lead 4 is electrically connected to the semiconductor element 6. As shown in FIG. 28, the fourth lead 4 is spaced apart from the first lead 1, the second lead 2, and the third lead 3. The fourth lead 4 is located between the second lead 2 and the third lead 3 in the y direction on the x1 side of the mounting portion 110 of the first lead 1 in the x direction. In the z direction, the fourth lead 4 is located on the z2 side of the first lead 1 as shown in FIG. 29. In the present embodiment, the fourth lead 4 is located at the same position as the second lead 2 and the third lead 3 in the z direction. The fourth lead 4 includes a fourth pad portion 410 and a fourth terminal 420.

The fourth pad portion 410 is a portion to which the wire 73 is bonded and has a rectangular (or: substantially rectangular) shape elongated in the y direction as viewed in the z direction. The fourth pad portion 410 has a fourth-pad-portion obverse surface 411. The fourth-pad-portion obverse surface 411 faces the z2 side in the z direction and has the wire 73 bonded thereto. The wire 73 is not specifically limited as to the material, the thickness, and the number to be provided. The fourth pad portion 410 is entirely covered with the sealing resin 8.

The fourth terminal 420 is connected to the fourth pad portion 410 and hence electrically connected to the second electrode 64 (the source electrode) of the semiconductor element 6 via the fourth pad portion 410 and the wire 73. The fourth terminal 420 serves as a source-sense terminal of the semiconductor device A60. The fourth terminal 420 has a width (a length in the y direction) smaller than the width (the length in the y direction) of the fourth pad portion 410. In addition, the fourth terminal 420 has a thickness (a length in the z direction) that is the same as the thickness (the length in the z direction) of the fourth pad portion 410 and also as the thickness of the first terminal 120. As shown in FIG. 28, the fourth terminal 420 is located at the center of the fourth pad portion 410 in the y direction on the x1 side in the x direction and. The position of the fourth terminal 420 is not specifically limited. The fourth terminal 420 extends in the x direction and has a portion protruding from the sealing resin 8. The shape of the fourth lead 4, however, is not limited to the one described above.

As shown in FIG. 29, at the resin end surface 83, the first terminal 120, the second terminal 220, the fourth terminal 420, and the third terminal 320 are spaced apart from each other in the y direction and arranged from the y1 side to the y2 side in the stated order. At the resin end surface 83, in addition, the first terminal 120 is spaced apart from the second terminal 220, the third terminal 320, and the fourth terminal 420 in the z direction. At the resin end surface 83, the second terminal 220, the third terminal 320, and the fourth terminal 420 are located at the same position in the z direction. At the resin end surface 83, the first terminal 120 is located on the side of the resin reverse surface 82 in the z direction (the z2 side in the z direction) with respect to the second terminal 220, the third terminal 320, and the fourth terminal 420.

In the present embodiment, the first terminal 120 and the second terminal 220 at the resin end surface 83 are spaced apart from each other in the y direction and also in the z direction. The creepage distance D between the first terminal 120 and the second terminal 220 along the resin end surface 83 is thus greater than in the creepage distance between two terminals located at the same position in the z direction. With the configurations described above, the semiconductor device A60 can achieve a higher dielectric strength. Note that the third terminal 320 and the fourth terminal 420 are each widely spaced apart on the resin end surface 83 from the first terminal 120. Hence, the creepage distance between the first terminal 120 and each of the third terminal 320 and the fourth terminal 420 along the resin end surface 83 is sufficiently large and will not present a problem. In addition, the semiconductor device A60 has a configuration in common with the semiconductor device A10 and thus achieves the same effect as the semiconductor device A10.

### First Variation:

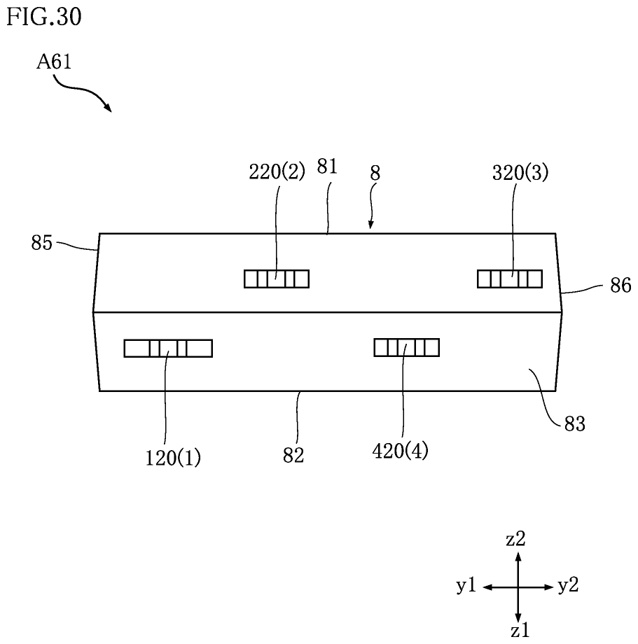

FIG. 30 is a front view of a semiconductor device A61 according to a first variation of the sixth embodiment and corresponds to FIG. 5. For the semiconductor device A61, the fourth lead 4 coincides with the first terminal 120 in position in the z direction. That is, at the resin end surface 83, the fourth terminal 420 is widely spaced apart from the 120, and thus has a sufficient creepage first terminal distance. This allows flexibility in determining the position of the fourth lead 4 in the z direction.

Although the present embodiment describes the case where the first terminal 120, the second terminal 220, the fourth terminal 420, and the third terminal 320 are arranged from the y1 side to the y2 side in the y direction in the stated order, the present disclosure is not limited thereto. In another example, the first terminal 120 may be located between the second terminal 220 and the fourth terminal 420 in the y direction.

### Seventh Embodiment

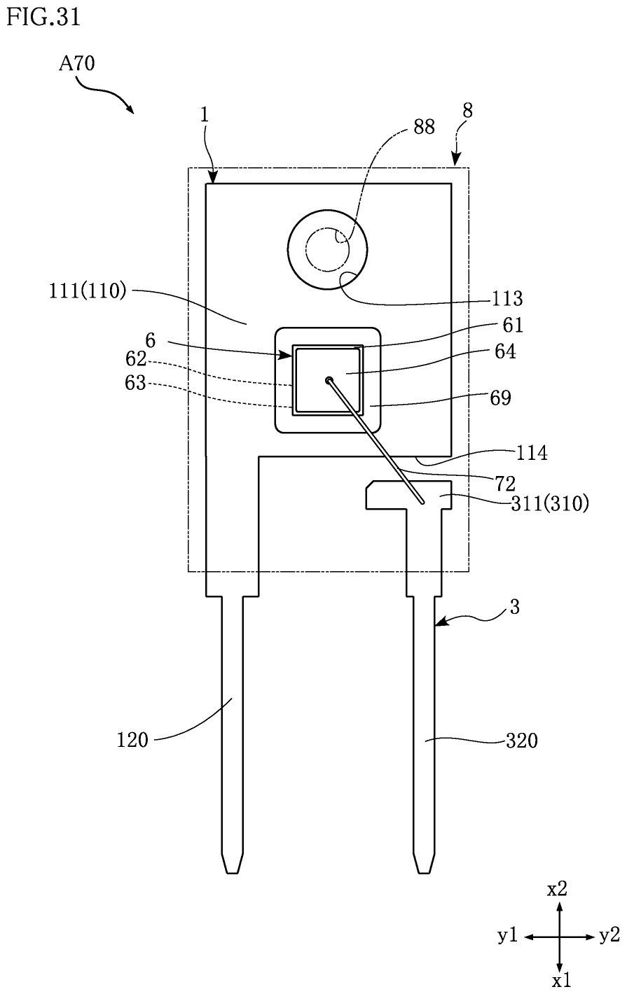

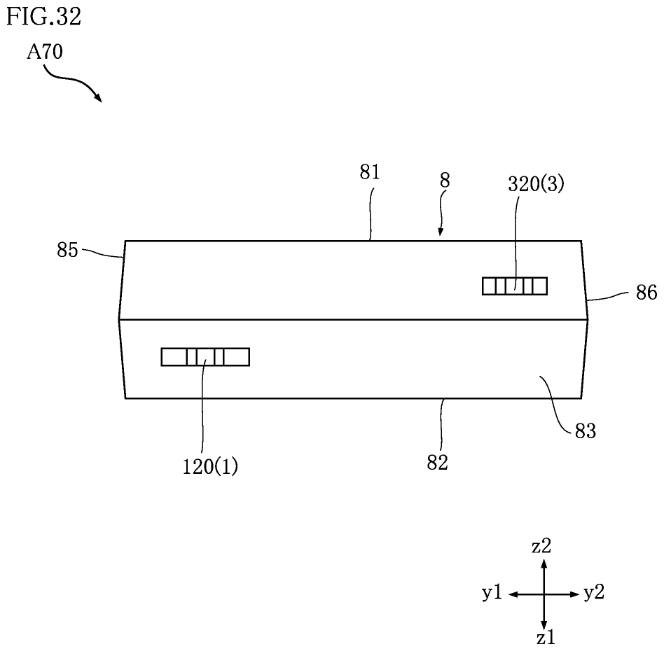

FIGS. 31 and 32 are views for illustrating a semiconductor device A70 according to a seventh embodiment. FIG. 31 is a plan view of the semiconductor device A70 and corresponds to FIG. 3. For convenience, FIG. 31 shows the sealing resin 8 as transparent and indicates the outline of the sealing resin 8 with an imaginary line (two-dot-dash line). FIG. 32 is a front view of the semiconductor device A70 and corresponds to FIG. 5. Different from the semiconductor device A10 of the first embodiment, the semiconductor device A70 of the present embodiment includes a semiconductor element 6 of a different type and does not include the second lead 2. With respect to the other configurations and operations, the present embodiment is similar to the first embodiment. The present embodiment may be combined with any variation of the first to sixth embodiments.

The present embodiment includes a diode as the semiconductor element 6. The semiconductor element 6 does not include a third electrode 65 on the element obverse surface 61. In the present embodiment, the first electrode 63 is a cathode electrode and the second electrode 64 is an anode electrode. The first lead 1 of the present embodiment is similar in shape to the first lead of the semiconductor device A50 of the fifth embodiment and includes the first terminal 120 connected to the end of the mounting-portion end surface 114 in the y1 side in the y direction. The semiconductor device A70 does not include the second lead 2. The first electrode 63 of the semiconductor element 6 is bonded to the mounting-portion obverse surface 111 via the bonding material 69 and electrically connected to the first lead 1. The wire 72 is bonded to the second electrode 64 of the semiconductor element 6 and the third-pad-portion obverse surface 311 of the third lead 3. This electrically connects the second electrode 64 of the semiconductor element 6 to the third lead 3. The first terminal 120 of the first lead 1, which is electrically connected to the first electrode 63, serves as a cathode terminal of the semiconductor device A70. The third terminal 320 of the third lead 3, which is electrically connected to the second electrode 64, serves as the anode terminal of the semiconductor device A70.

In the present embodiment, the first terminal 120 and the third terminal 320 at the resin end surface 83 are spaced apart from each other in the y direction and also in the z direction. The creepage distance between the first terminal 120 and the third terminal 320 along the resin end surface 83 is thus greater than in the creepage distance between two terminals located at the same position in the z direction. With the configurations described above, the semiconductor device A70 can achieve a higher dielectric strength. In addition, the semiconductor device A70 has a configuration in common with the semiconductor device A10 and thus achieves the same effect as the semiconductor device A10.

Although the first to sixth embodiments describe examples where the semiconductor element 6 is a transistor, and the seventh embodiment describes an example where the semiconductor element 6 is a diode, the present disclosure is not limited thereto. The type of the semiconductor element 6 is not specifically limited, and other types of semiconductor elements such as integrated circuits may be used. In addition, although the first to seventh embodiments describe the case where two to four terminals are included, he present disclosure is not limited thereto. The number of terminals to be included is not specifically limited and can be determined according to the number and arrangement of electrodes disposed on the element obverse surface 61 of the semiconductor element 6. In addition, although the first to seventh embodiments describe the case where all the terminals protrude from the resin end surface 83, the present disclosure is not limited thereto. One or more terminals may protrude from any of the resin first side surface 84, the resin second side surface 85, and the resin third side surface 86.

The semiconductor devices according to the present disclosure are not limited to the embodiments described above. The specific configuration of each part of a semiconductor device according to the present disclosure may suitably be designed and changed in various manners. The present disclosure includes the embodiments described in the following clauses.
Clause 1.
A semiconductor device comprising:
a semiconductor element (6);
a conductive member (5) electrically connected to the semiconductor element; and
a sealing resin (8) covering the semiconductor element,
wherein the conductive member includes:
a first lead (1) including a mounting portion (110) on which the semiconductor element is mounted and a first terminal (120) connected to the mounting portion; and
a second lead (2) including a second terminal (220),
each of the first terminal and the second terminal includes a portion protruding from the sealing resin in a first direction orthogonal to a thickness direction of the mounting portion,
the sealing resin includes:
a resin obverse surface (81) and a resin reverse surface (82) facing away from each other in the thickness direction; and
a resin end surface (83) connected to the resin obverse surface and the resin reverse surface and facing in a direction in which the first terminal and the second terminal protrude, and
at the resin end surface, the first terminal and the second terminal are spaced apart from each other in a second direction orthogonal to the thickness direction and the first direction and spaced apart from each other in the thickness direction.
Clause 2.
The semiconductor device according to Clause 1, wherein, at the resin end surface, the first terminal is offset toward the resin reverse surface in the thickness direction with respect to the second terminal.
Clause 3. (Second embodiment, FIG. 18)
The semiconductor device according to Clause 1 or 2, wherein the first terminal includes a first bent portion (121) that is bent and exposed from the sealing resin and a first tip portion (122) connected to the first bent portion and extending in the first direction,
the second terminal includes a second bent portion (221) that is bent and exposed from the sealing resin and a second tip portion (222) connected to the second bent portion and extending in the first direction, and
the first tip portion and the second tip portion are located at a same position in the thickness direction.
Clause 4. (Third embodiment, FIG. 21)
The semiconductor device according to any one of Clauses 1 to 3, wherein the second lead includes a pad portion (210) connected to the second terminal and covered with the sealing resin,
the second terminal includes a second straight portion (223) extending in the first direction and a second connecting portion (224) connected to the pad portion and the second straight portion,
the second connecting portion is covered with the sealing resin and inclined relative to the pad portion and the second straight portion, and
the pad portion is located on a side of the resin reverse surface in the thickness direction with respect to the second straight portion.
Clause 5.
The semiconductor device according to Clause 4, further bonded comprising a connecting member (71) d to the semiconductor element and the pad portion.
Clause 6. (Second variation of First embodiment, FIG. 10; Fourth embodiment, FIG. 24)
The semiconductor device according to any one of Clauses 1 to 5, wherein the first terminal includes a first straight portion (123) extending in the first direction and a first connecting portion (124) connected to the mounting portion and the first straight portion, and
the first connecting portion is covered with the sealing resin and inclined relative to the mounting portion and the first straight portion.
Clause 7.
The semiconductor device according to any one of Clauses 1 to 6, wherein the mounting portion includes a mounting-portion obverse surface (111) to which the semiconductor element is bonded and a mounting-portion reverse surface (112) facing away from the mounting-portion obverse surface in the thickness direction, and
the mounting-portion reverse surface is exposed from the resin reverse surface.
Clause 8.
The semiconductor device according to any one of Clauses 1 to 7, wherein a dimension of the mounting portion in the thickness direction is greater than a dimension of the first terminal in the thickness direction.
Clause 9.
The semiconductor device according to any one of Clauses 1 to 8, wherein the sealing resin includes:
a resin first side surface (84) connected to the resin obverse surface and the resin reverse surface and facing away from the resin end surface; and
a resin second side surface (85) and a resin third side surface (86) connected to the resin obverse surface, the resin reverse surface, the resin end surface, and the resin first side surface, and
the conductive member is not exposed from the resin first side surface, the resin second side surface, and the resin third side surface.
Clause 10.
The semiconductor device according to any one of Clauses 1 to 9, wherein the conductive member includes a third lead (3) including a third terminal (320), and
the third terminal includes a portion protruding from the resin end surface, and at the resin end surface, the third terminal is spaced apart from the first terminal and the second terminal in the second direction.
Clause 11.
The semiconductor device according to Clause 10, wherein at the resin end surface, the third terminal is spaced apart from the first terminal in the thickness direction and located on a same side as the second terminal in the thickness direction with respect to the first terminal.
Clause 12.
The semiconductor device according to Clause 10 or 11, wherein at the resin end surface, the third terminal is located on a side opposite the second terminal in the second direction with respect to the first terminal.
Clause 13. (Sixth embodiment, FIG. 28)
The semiconductor device according to any one of Clauses 10 to 12, wherein the conductive member includes a fourth lead (4) including a fourth terminal (420), and
the fourth terminal includes a portion protruding from the resin end surface, and at the resin end surface, the fourth terminal is spaced apart from the first terminal or the third terminal in the second direction.
Clause 14.
The semiconductor device according to any one of Clauses 1 to 13, wherein the semiconductor element includes an element obverse surface (61) and an element reverse surface (62) facing away from each other in the thickness direction, a first electrode (63) disposed on the element reverse surface, and a second electrode (64) disposed on the element obverse surface,
the first electrode is bonded to the mounting portion, and
the second electrode is electrically connected to the second lead.

### REFERENCE NUMERALS

A10 to A17, A20, A21, A30, A40: Semiconductor device
A50, A51, A60, A61, A70: Semiconductor device
5: Conductive member 1: First lead
110: Mounting portion
111: Mounting-portion obverse surface
112: Mounting-portion reverse surface
113: Mounting-portion through-hole
114: Mounting-portion end surface
115: Reverse-surface recess 120: First terminal
121: First bent portion
122: First tip portion 123: First straight portion
124: First connecting portion
125: First-terminal reverse surface 2: Second lead
210: Second pad portion
211: Second-pad-portion obverse surface
212: Second-pad-portion reverse surface
220: Second terminal 221: Second bent portion
222: Second tip portion
223: Second straight portion 224: Second connecting portion
3: Third lead 310: Third pad portion
311: Third-pad-portion obverse surface
312: Third-pad-portion reverse surface
320: Third terminal 321: Third bent portion
322: Third tip portion 323: Third straight portion
324: Third connecting portion
4: Fourth lead 410: Fourth pad portion
411: Fourth-pad-portion obverse surface 420: Fourth terminal
6: Semiconductor element 60: Element body
61: Element obverse surface 62: Element reverse surface
63: First electrode 64: Second electrode
65: Third electrode
69: Bonding material
81: Resin obverse surface 71, 72, 73: Wire 8: Sealing resin
82: Resin reverse surface 83: Resin end surface
84: Resin first side surface
85: Resin second side surface 86: Resin third side surface
88: Resin through-hole

1. A semiconductor device comprising:
a semiconductor element;
a conductive member electrically connected to the semiconductor element; and
a sealing resin covering the semiconductor element,
wherein the conductive member includes:
a first lead including a mounting portion on which the semiconductor element is mounted and a first terminal connected to the mounting portion; and
a second lead including a second terminal,
each of the first terminal and the second terminal includes a portion protruding from the sealing resin in a first direction orthogonal to a thickness direction of the mounting portion,
the sealing resin includes:
a resin obverse surface and a resin reverse surface facing away from each other in the thickness direction; and
a resin end surface connected to the resin obverse surface and the resin reverse surface and facing in a direction in which the first terminal and the second terminal protrude, and
at the resin end surface, the first terminal and the second terminal are spaced apart from each other in a second direction orthogonal to the thickness direction and the first direction and spaced apart from each other in the thickness direction.

2. The semiconductor device according to claim 1, wherein, at the resin end surface, the first terminal is offset toward the resin reverse surface in the thickness direction with respect to the second terminal.

3. The semiconductor device according to claim 1, wherein the first terminal includes a first bent portion that is bent and exposed from the sealing resin and a first tip portion connected to the first bent portion and extending in the first direction,
the second terminal includes a second bent portion that is bent and exposed from the sealing resin and a second tip portion connected to the second bent portion and extending in the first direction, and
the first tip portion and the second tip portion are located at a same position in the thickness direction.

4. The semiconductor device according to claim 1, wherein the second lead includes a pad portion connected to the second terminal and covered with the sealing resin,
the second terminal includes a second straight portion extending in the first direction and a second connecting portion connected to the pad portion and the second straight portion,
the second connecting portion is covered with the sealing resin and inclined relative to the pad portion and the second straight portion, and
the pad portion is located on a side of the resin reverse surface in the thickness direction with respect to the second straight portion.

5. The semiconductor device according to claim 4, further comprising a connecting member bonded to the semiconductor element and the pad portion.

6. The semiconductor device according to claim 1, wherein the first terminal includes a first straight portion extending in the first direction and a first connecting portion connected to the mounting portion and the first straight portion, and
the first connecting portion is covered with the sealing resin and inclined relative to the mounting portion and the first straight portion.

7. The semiconductor device according to claim 1, wherein the mounting portion includes a mounting-portion obverse surface to which the semiconductor element is bonded and a mounting-portion reverse surface facing away from the mounting-portion obverse surface in the thickness direction, and
the mounting-portion reverse surface is exposed from the resin reverse surface.

8. The semiconductor device according to claim 1, wherein a dimension of the mounting portion in the thickness direction is greater than a dimension of the first terminal in the thickness direction.

9. The semiconductor device according to claim 1, wherein the sealing resin includes:
a resin first side surface connected to the resin obverse surface and the resin reverse surface and facing away from the resin end surface; and
a resin second side surface and a resin third side surface connected to the resin obverse surface, the resin reverse surface, the resin end surface, and the resin first side surface, and
the conductive member is not exposed from the resin first side surface, the resin second side surface, and the resin third side surface.

10. The semiconductor device according to claim 1, wherein the conductive member includes a third lead including a third terminal, and
the third terminal includes a portion protruding from the resin end surface, and at the resin end surface, the third terminal is spaced apart from the first terminal and the second terminal in the second direction.

11. The semiconductor device according to claim 10, wherein at the resin end surface, the third terminal is spaced apart from the first terminal in the thickness direction and located on a same side as the second terminal in the thickness direction with respect to the first terminal.

12. The semiconductor device according to claim 10, wherein at the resin end surface, the third terminal is located on a side opposite the second terminal in the second direction with respect to the first terminal.

13. The semiconductor device according to claim 10, wherein the conductive member includes a fourth lead including a fourth terminal, and
the fourth terminal includes a portion protruding from the resin end surface, and at the resin end surface, the fourth terminal is spaced apart from the first terminal or the third terminal in the second direction.

14. The semiconductor device according to claim 1, wherein the semiconductor element includes an element obverse surface and an element reverse surface facing away from each other in the thickness direction, a first electrode disposed on the element reverse surface, and a second electrode disposed on the element obverse surface,
the first electrode is bonded to the mounting portion, and
the second electrode is electrically connected to the second lead.
